(19) United States
(12) Patent Application Publication
(10) Pub. No.: US 2017/0073547 A1
(43) Pub. Date: Mar. 16, 2017

(54) Curable Composition, Temporary Bonding Material, and Method for Temporarily Bonding Component Part and Substrate By Same

(71) Applicant: Central Glass Company, Ltd., Ube-shi, Yamaguchi (JP)

(72) Inventors: Tsuyoshi OGAWA, Iruma-gun, Saitama (JP); Kiminori SATO, Kawegoe-shi, Saitama (JP); Akira KOBAYASHI, Fujimino-shi, Saitama (JP)

(21) Appl. No.: 15/122,646

(22) PCT Filed: Apr. 15, 2015
(86) PCT No.: PCT/JP2015/061531

§ 371 Date: Aug. 31, 2016

(30) Foreign Application Priority Data
Apr. 24, 2014 (JP) 2014-089771
Apr. 24, 2014 (JP) 2014-089772
Apr. 9, 2015 (JP) 2015-079959

(51) Int. Cl. C09J 4/00; C08F 2/44; H01L 21/683; C08K 3/26; C08K 3/22; C08F 2/50; C09J 11/04

(52) U.S. Cl. CPC C09J 4/00; C08F 2/50; C08F 2/44; C09J 11/04; C08K 3/26; C08K 3/22; H01L 21/6836; C09J 2433/00; C08K 2003/262; C08K 2003/2203; C08K 2003/2206; H01L 2221/68381

(57) ABSTRACT

A first curable composition has flowability and include a photopolymerizable group-containing silicone compound (A), a photopolymerization initiator, a photoacid generator and at least one kind of metal compound selected from the group consisting of metal carbonates, metal hydroxides and metal oxides. This curable composition provides a temporary bonding material capable of easily temporarily bonding a component part and a substrate, without trapping an air bubble in a temporary bonding surface of the component, and allowing easy separation of the component part and the substrate after performing various processing on the component part.

### FIELD OF THE INVENTION

The present invention relates to a curable composition, a temporary bonding material, and a method for temporarily bonding a component part to a substrate by the use of the curable composition or temporary bonding material.

### BACKGROUND ART

In the processing of optical lens, optical component parts, prisms, semiconductor packages and the like, frequently used is a processing method which includes the steps of temporarily bonding a workpiece (target work) to a substrate via a temporary bonding material, performing desired processing such as cutting, polishing, grinding or drilling on the workpiece, and then, separating the workpiece from the substrate. This processing method conventionally uses a hot-melt adhesive or a double-sided tape as the temporary bonding material so that the workpiece can be separated from the substrate by e.g. dissolving the temporary bonding material in an organic solvent after the processing of the workpiece.

In the case of using the hot-melt adhesive, it is necessary to apply heat of 100° C. or higher to the hot-melt adhesive for the bonding of the workpiece. The type of the component part usable as the workpiece is thus limited. It is also necessary to use the organic solvent for the separation of the workpiece. The use of such an organic solvent leads to not only a problem that the washing treatment for removal of the alkaline solution or halogenated organic solvent is complicated but also a working environmental problem.

In the case of using the double-sided tape, the double-sided tape is weak in bonding strength and low in chipping resistance during the processing even though the double-sided tape has flexibility. Further, the workpiece cannot be separated without applying heat of 100° C. or higher to the double-sided tape.

Depending on the kind of the processing, the processing is performed on the workpiece under high-temperature conditions. It is accordingly demanded to develop a temporary bonding material that withstands high-temperature processing and shows good bonding and separation properties.

On the other hand, there are known a method of separating the workpiece by decomposing the temporary bonding material under laser irradiation etc. (Patent Document 1) and a method of separating the workpiece by pouring a solvent into a through hole of the substrate and thereby dissolving the temporary bonding material in the solvent (Patent Document 2).

There is also known a method using, as the temporary bonding material, a semiconductor-processing adhesive tape having an adhesive layer formed of an adhesive composition containing an adhesive component, an acid generator and an alkali metal carbonate (Patent Document 3).

### PRIOR ART DOCUMENTS

### Patent Documents

Patent Document 1: Japanese Laid-Open Patent Publication No. 2004-64040
Patent Document 2: Japanese Laid-Open Patent Publication No. 2008-34623
Patent Document 3: Japanese Laid-Open Patent Publication No. 2012-107194

### SUMMARY OF THE INVENTION

### Problems to be Solved by the Invention

In the method of Patent Document 1, it is necessary to use a separation device with a special laser light source. In the method of Patent Document 2, it is necessary to use the substrate in which the through hole is formed for contact of the solvent with the temporary bonding material. Furthermore, it is necessary in the method of Patent Document 3 that the semiconductor-processing adhesive tape is uniformly brought into contact with and adhered to the wafer without an air bubble being trapped in protrusions and recesses of a circuit forming area of the wafer during the temporarily bonding of the wafer to the substrate via the adhesive composition. This adhering operation may take a time. In the case where an air bubble is trapped in the protrusions and recesses of the circuit forming area of the wafer and in the case where there is a time gap until the processing of the wafer, it may become difficult to perform desired processing on the wafer or separate the wafer in the subsequent processing or separation step. There is thus a demand for easily bonding the wafer and the substrate in a short time.

Although various workpiece separation methods are known as mentioned above, a more simple and easier workpiece separation method is demanded.

The present invention has been made in view of the above problems. It is an object of the present invention to provide a curable composition usable in a temporary bonding material for easily temporarily bonding a component part as a workpiece to a substrate without, even when the component part has a temporary bonding surface with protrusions and recesses, trapping an air bubble in such a temporary bonding surface of the component part, and allowing easy separation of the component part from the substrate after processing the component part. It is also an object of the present invention to provide a temporary bonding material using the curable composition and a method for temporarily bonding a component part to a substrate by the use of the temporary bonding material. In particular, the present invention is intended to provide a wafer-processing temporary bonding material suitably usable for the temporary bonding of a wafer and a substrate in semiconductor wafer processing and a method for temporarily bonding a wafer to a substrate.

### Means for Solving the Problems

As a result of extensive researches, the present inventors have found that it is possible to achieve the above objects by the use of a first curable composition having flowability and containing at least a photopolymerizable group-containing silicone compound (A), a photopolymerization initiator that absorbs light of wavelength 400 nm or more, a photoacid generator that absorbs light of wavelength less than 400 nm and at least one kind of metal compound selected from the group consisting of metal carbonates, metal hydroxides and metal oxides. The present invention is based on this finding.

Namely, the present invention includes the following inventive aspects 1 to 16.

[Inventive Aspect 1]

A first curable composition having flowability and comprising:

a photopolymerizable group-containing silicone compound (A);

a photopolymerization initiator that absorbs light of wavelength 400 nm or more;

a photoacid generator that absorbs light of wavelength less than 400 nm; and

at least one kind of metal compound selected from the group consisting of metal carbonates, metal hydroxides and metal oxides.

[Inventive Aspect 2]

The first curable composition according to Inventive Aspect 1, wherein the photopolymerizable group-containing silicone compound (A) is either a cage-like silsesquioxane compound with an acryloyl group or a methacryloyl group, or a hydrolysis condensate of a composition containing at least an alkoxysilane compound of the general formula (3)

(R²)ᵥSi(OR³)₄₋ᵥ (3)

where R² is an organic moiety having at least one kind of group selected from the group consisting of acryloyl and methacryloyl groups; R³ is a methyl group or an ethyl group; v is an integer of 1 to 3; and, when there exist a plurality of R² and a plurality of R³, R² may be of the same kind or different kinds, and R³ may be of the same kind or different kinds.

[Inventive Aspect 3]

A temporary bonding material comprising at least a first temporary bonding material layer in the form of a cured film of the first curable composition according to Inventive Aspect 1 or 2.

[Inventive Aspect 4]

The temporary bonding material according to Inventive Aspect 3, further comprising a second temporary bonding material layer formed of a second curable composition containing at least a hydrolysis condensate of a photopolymerizable group-containing and hydrolyzable group-containing silicone compound (B).

[Inventive Aspect 5]

The temporary bonding material according to Inventive Aspect 4, wherein the hydrolysis condensate of the photopolymerizable group-containing and hydrolyzable group-containing silicone compound (B) is a hydrolysis condensate obtained by hydrolysis and condensation of a composition containing at least an alkoxysilane compound of the general formula (5)

(R⁶)ₛSi(OR⁷)₄₋ₛ (5)

where R⁶ is an organic moiety having at least one kind of group selected from the group consisting of acryloyl and methacryloyl groups; R⁷ is a methyl group or an ethyl group; s is an integer of 1 to 3; and, when there exist a plurality of R⁶ and a plurality of R⁷, R⁶ may be of the same kind or different kinds, and R⁷ may be of the same kind or different kinds.

[Inventive Aspect 6]

The temporary bonding material according to Inventive Aspect 4 or 5, wherein the second curable composition further contains a photopolymerization initiator.

[Inventive Aspect 7]

A structural unit comprising a component part and a substrate temporarily bonded to each other via the temporary bonding material according to any one of Inventive Aspects 3 to 6.

[Inventive Aspect 8]

A method for temporarily bonding a component part to a substrate, the method comprising the following steps:

a first step of stacking the component part and the substrate together with an uncured temporary bonding material interposed therebetween, the uncured temporary bonding material having at least a layer of the first curable composition according to Inventive Aspect 1 or 2;

a second step of irradiating the uncured temporary bonding material with light of wavelength 400 nm or more, thereby curing the uncured temporary bonding material to form a structural unit in which the component part and the substrate are temporarily bonded to each other via the cured temporary bonding material;

a third step of processing the component part of the structural unit; and

a fourth step of, after the processing, separating the component part from the structural unit by irradiating the cured temporary bonding material of the structural unit with light of wavelength less than 400 nm.

[Inventive Aspect 9]

The method according to Inventive Aspect 8, wherein the uncured temporary bonding material has a second temporary bonding material layer arranged in contact with the substrate and the layer of the first curable composition; and wherein the second temporary bonding material layer is a layer of a second curable composition containing at least a hydrolysis condensate of a photopolymerizable group-containing and hydrolyzable group-containing silicone compound (B).

[Inventive Aspect 10]

The method according to Inventive Aspect 9, wherein the hydrolysis condensate of the photopolymerizable group-containing and hydrolyzable group-containing silicone compound (B) is a hydrolysis condensate obtained by hydrolysis and condensation of a composition containing at least an alkoxysilane compound of the general formula (5)

(R⁶)ₛSi(OR⁷)₄₋ₛ (5)

where R⁶ is an organic moiety having at least one kind of group selected from the group consisting of acryloyl and methacryloyl groups; R⁷ is a methyl group or an ethyl group; s is an integer of 1 to 3; and, when there exist a plurality of R⁶ and a plurality of R⁷, R⁶ may be of the same kind or different kinds, and R⁷ may be of the same kind or different kinds.

[Inventive Aspect 11]

The method according to any one of Inventive Aspects 8 to 10, further comprising removing a residue of the cured temporary bonding material from the substrate and then recycling the substrate.

[Inventive Aspect 12]

A wafer-processing temporary bonding material for temporarily bonding a wafer, which has a front surface with a circuit forming area and a back surface to be processed, to a support medium by being interposed between the front surface of the wafer and the support medium, wherein the wafer-processing temporary bonding material is the temporary bonding material according to any one of Inventive Aspects 3 to 6.

[Inventive Aspect 13]

A method for temporarily bonding a wafer to a support medium, the wafer having a front surface with a circuit forming area and a back surface to be processed, the method comprising the following steps:

a step (a) of stacking the wafer and the support medium together with an uncured wafer-processing temporary bonding material interposed between the front surface of the wafer and the support medium, the uncured wafer-processing temporary bonding material having at least a layer of the first curable composition according to Inventive Aspect 1 or 2;

a step (b) of irradiating the uncured wafer-processing temporary bonding material with light of wavelength 400 nm or more, thereby curing the uncured wafer-processing temporary bonding material to form a wafer-processing structural unit in which the front surface of the wafer is temporarily bonded to the support medium via the cured wafer-processing temporary bonding material;

a step (c) of processing the back surface of the wafer of the wafer-processing structural unit; and

a step (d) of, after the processing, separating the wafer from the wafer-processing structural unit by irradiating the cured wafer-processing temporary bonding material of the wafer-processing structural unit with light of wavelength less than 400 nm.

[Inventive Aspect 14]

The method according to Inventive Aspect 13, wherein the uncured wafer-processing temporary bonding material has a second temporary bonding material layer arranged in contact with the support medium and the layer of the first curable composition; and wherein the second temporary bonding material layer is a layer of a second curable composition containing at least a hydrolysis condensate of a photopolymerizable group-containing and hydrolyzable group-containing silicone compound (B).

[Inventive Aspect 15]

The method according to Inventive Aspect 14, wherein the hydrolysis condensate of the photopolymerizable group-containing and hydrolyzable group-containing silicone compound (B) is a hydrolysis condensate obtained by hydrolysis and condensation of a composition containing at least an alkoxysilane compound of the general formula (5)

(R⁶)ₛSi(OR⁷)₄₋ₛ (5)

where R⁶ is an organic moiety having at least one kind of group selected from the group consisting of acryloyl and methacryloyl groups; R⁷ is a methyl group or an ethyl group; s is an integer of 1 to 3; and, when there exist a plurality of R⁶ and a plurality of R⁷, R⁶ may be of the same kind or different kinds, and R⁷ may be of the same kind or different kinds.

[Inventive Aspect 16]

The method according to any one of Inventive Aspects 13 to 15, further comprising removing a residue of the cured wafer-processing temporary bonding material from the support medium and then recycling the support medium.

In the present specification, the term “flowability” refers to the property of being deformed in shape by an external physical action and, more specifically, refers to e.g. having a viscosity of 10,000,000 mPa·s under standard conditions (25° C. and 1 atmospheric pressure).

### Effects of the Invention

It is possible according to the present invention to provide the curable composition usable in the temporary bonding material for temporarily bonding the component part as the workpiece to the substrate without, even when the component part has a temporary bonding surface with protrusions and recesses, trapping an air bubble in such a temporary bonding surface of the component part, and allowing easy separation of the component part from the substrate after processing the component part. It is also possible according to the present invention to provide the temporary bonding material using the curable composition and the method for temporarily bonding the component part to the substrate by the use of the temporary bonding material. In particular, there are provided according to the present invention the wafer-processing temporary bonding material suitably usable for the temporary bonding of the wafer and the support medium in semiconductor wafer processing and the method for temporarily bonding the wafer to the support medium.

### BRIEF DESCRIPTION OF DRAWINGS

FIG. 1 is a cross-sectional view showing one example of structural unit according to the present invention.

FIG. 2 is a cross-sectional view showing another example of structural unit according to the present invention.

FIG. 3 is a cross-sectional view showing a method for temporarily bonding a component part to a substrate according to one embodiment of the present invention.

FIG. 4 is a cross-sectional view showing a method for temporarily bonding a component part to a substrate according to another embodiment of the present invention.

### DETAILED DESCRIPTION OF EMBODIMENTS

Hereinafter, the present invention will be described below in detail. It should be noted that the present invention is not limited to the following embodiments and descriptions thereof.

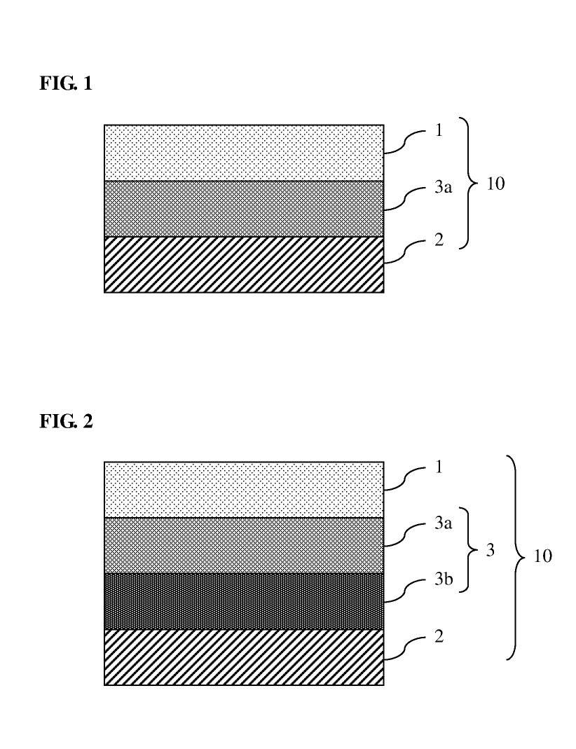

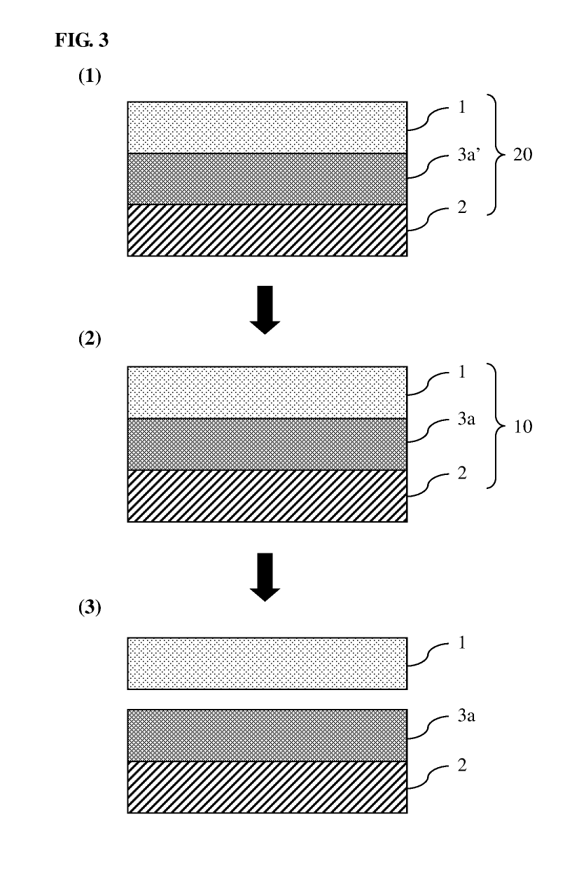

As shown in FIG. 1, a structural unit 10 according to one embodiment of the present invention includes a component part 1, a substrate 2 supporting thereon the component part 1 and a temporary bonding material 3 interposed between the component part 1 and the substrate 2. The temporary bonding material 3 has at least a first temporary bonding material layer 3a formed by curing a first curable composition according to the present invention. The temporary bonding material 3 may have a second temporary bonding material layer 3b (see FIG. 2). In the case where the temporary bonding material 3 has the second temporary bonding material layer 3b, the first temporary bonding material layer 3a is arranged in contact with the component part 1 and the second temporary bonding material layer 3b; and the second temporary bonding material layer 3b is arranged in contact with the first temporary bonding material layer 3a and the substrate 2.

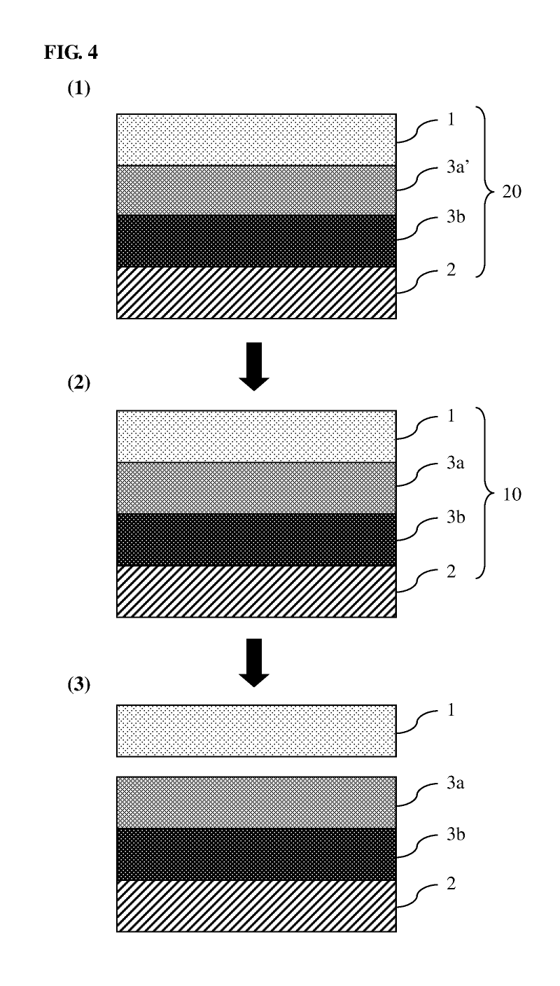

A temporary bonding method according to one embodiment of the present invention includes the following steps. As shown in area (1) of FIG. 3, a stacked unit 20 is formed in which the component part 1 and the substrate 2 are stacked together via a layer 3a′ of the first curable composition. The first curable composition layer 3a′ of the stacked unit 20 is cured to the first temporary bonding material layer 3a by irradiation with light of wavelength 400 nm or more so that the component part 1 and the substrate 2 are temporarily bonded to each other via the first temporary bonding material layer 3a as shown in area (2) of FIG. 3. Then, various processing is performed on the component part 1 of the resulting temporarily bonded unit (structural unit 10). After the processing, the component part 1 is separated from the structural unit 10 by irradiating at least the first temporary bonding material layer 3a with light of wavelength less than 400 nm as shown in area (3) of FIG. 3.

A temporary bonding method according to another embodiment of the present invention includes the following steps. As shown in area (1) of FIG. 4, the component part 1 and the substrate are stacked together via a layer 3a′ of the first curable composition and the second temporary bonding material layer 3b such that the layer 3a′ of the first curable composition is in contact with the component part 1 and the second temporary bonding material layer 3b and such that the secondary temporary bonding material layer 3b is in contact with the layer 3a′ of the first curable composition and the substrate 2. The first curable composition layer 3a′ of the stacked unit 20 is cured to the first temporary bonding material layer 3a by irradiation with light of wavelength 400 nm or more so that the component part 1 and the substrate 2 are temporarily bonded to each other via the first temporary bonding material layer 3a and the second temporary bonding material layer as shown in area (2) of FIG. 4. At this time, the second temporary bonding material layer 3b may also be irradiated with light of wavelength 400 nm or more. Then, various processing is performed on the component part 1 of the resulting temporarily bonded unit (structural unit 10). After the processing, the component part 1 is separated from the structural unit 10 by irradiating at least the first temporary bonding material layer 3a with light of wavelength less than 400 nm as shown in area (3) of FIG. 4.

1. First Curable Composition

The first curable composition according to the present invention contains at least a photopolymerizable group-containing silicone compound (A), a photopolymerization initiator that absorbs light of wavelength 400 nm or more, a photoacid generator that absorbs light of wavelength less than 400 nm and one kind of metal compound, or more kinds of metal compounds, selected from the group consisting of metal carbonates, metal hydroxides and metal oxides.

It is preferable that the first curable composition contains, relative to the amount of the photopolymerizable group-containing silicone compound (A), 0.01 to 10 mass % of the photopolymerization initiator, 10 to 100 mass % of the photoacid generator and 10 to 100 mass % of the one or more metal compounds selected from the group consisting of metal carbonates, metal hydroxides and metal oxides.

[Photopolymerizable Group-Containing Silicone Compound (A)]

The photopolymerizable group-containing silicone compound (A) (hereinafter sometimes simply referred to as “silicone compound (A)”) is a silicone compound containing a photopolymerizable group. This photopolymerizable group refers to a functional group capable of polymerizing with the silicone compound (A) or the other polymerizable group-containing compound under light irradiation. Examples of the photopolymerizable group include, but are not limited to, an acryloyl group and a methacryloyl group.

The silicone compound (A) may have, and preferably has, flowability.

Depending on the material of the component part and the temperature conditions for the processing of the component part in the temporarily bonded state, the silicone compound (A) may have a 5% weight reduction temperature (T_{d5}) of 250° C. or higher as determined by thermogravimetric analysis. It is preferable that the 5% weight reduction temperature of the silicone compound (A) is 280° C. or higher.

The silicone compound (A) can be, but is not limited to, a cage-like silsesquioxane compound with an acryloyl group or a methacryloyl group. One example of such a silsesquioxane compound is a cage-like silsesquioxane compound represented by the following general formula (1) (sometimes referred to as “cage-like silsesquioxane compound (1)”). The cage-like silsesquioxane compound (1) has flowability and thus can suitably be used in the first curable composition.

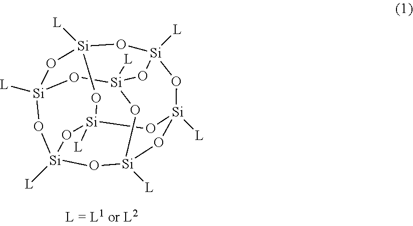

In the general formula (1), L is either L¹ or L² with the proviso that the number of L¹ is 1 to 8 and the total number of L¹ and L² is 8; L¹ is a monovalent organic moiety having an acryloyl group or a methacryloyl group; L² is an organic moiety inert to the photopolymerization initiator; and, when there exist a plurality of L¹ and a plurality of L², L¹ may be of the same kind or different kinds, and L² may be of the same kind or different kinds.

The moiety L¹ can be, but is not limited to, an organic moiety represented by the following formula (L-1).

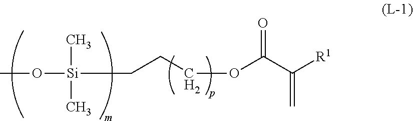

In the formula (L-1), m is an integer of 1 to 2; p is an integer of 1 to 3; and R¹ is a hydrogen atom or a methyl group.

Specific examples of the organic moiety represented by the formula (L-1) are those shown below.

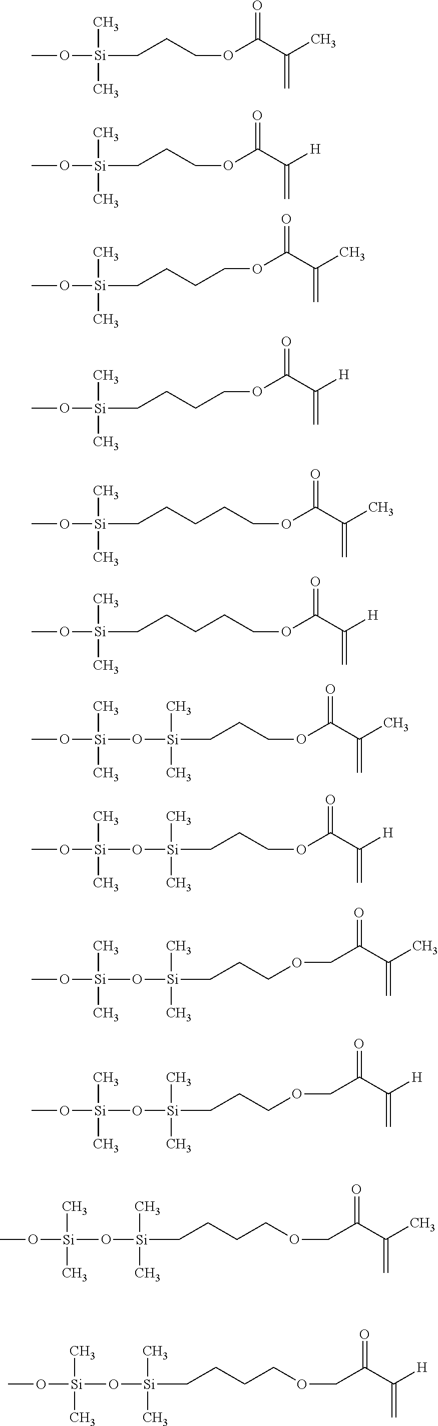

The moiety L² can be, but is not limited to, an organic moiety represented by the following formula (L-2-A) or (L-2-B).

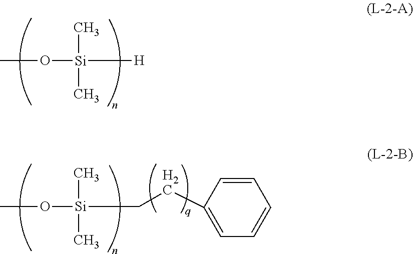

In the formulas (L-2-A) and (L-2-B), n is an integer of 1 to 2; and q is an integer of 2 to 5.

Specific examples of the organic moiety represented by the formula (L-2-A) or (L-2-B) are those shown below.

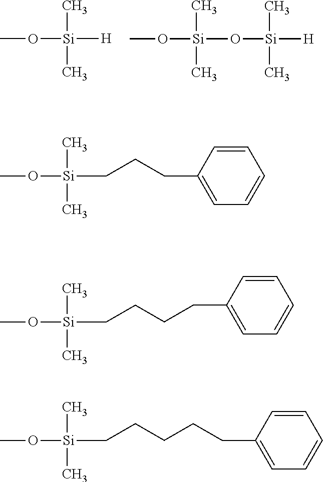

The cage-like silsesquioxane compound (1) may be of a single kind or two or more kinds with different moieties L. An organic silicone compound, such as a cage-like silsesquioxane compound represented by the following general formula (2) (sometimes referred to as “cage-like silsesquioxane compound (2)”), may be used in addition to the cage-like silsesquioxane compound (1).

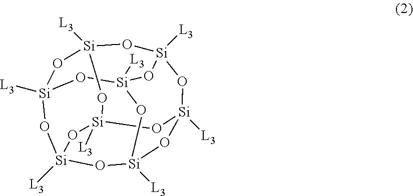

In the general formula (2), L³ has the same meaning as L²; and eight L³ may be of the same kind or different kinds.

The silicone compound (A) can alternatively be, but is not limited to, a hydrolysis condensate of a composition containing at least an alkoxysilane compound represented by the following general formula (3) (sometimes referred to as “alkoxysilane compound (3)”). (This hydrolysis condensate is sometimes referred to as “hydrolysis condensate (3)”.)

(R²)ᵥSi(OR³)₄₋ᵥ (3)

In the general formula (3), R² is an organic moiety having at least one kind of group selected from the group consisting of acryloyl and methacryloyl groups; R³ is a methyl group or an ethyl group; v is an integer of 1 to 3; and, when there exist a plurality of R² and a plurality of R³, R² may be of the same kind or different kinds, and R³ may be of the same kind or different kinds.

Examples of the organic moiety having at least one selected from the group consisting of acryloyl and methacryloyl groups include, but are not limited to, methacryloyloxyalkyl groups and acryloyloxyalkyl groups.

The alkoxysilane compound (3) may be of a single kind or two or more kinds. Specific examples of the alkoxysilane compound (3) include, but are not limited to, the following: trialkoxysilane compounds such as 3-(trimethoxysilyl)propylmethacrylate, 3-(triethoxysilyl)propylmethacrylate, 3-(trimethoxysilyl)propylacrylate, 3-(triethoxysilyl)propylacrylate, methacryloxymethyltriethoxysilane and methacryloxymethyltrimethoxysilane; dialkoxysilane compounds such as (3-acryloxypropyl)methyldimethoxysilane, (methacryloxymethyl)methyldiethoxysilane, (methacryloxymethyl)methyldimethoxysilane, methacryloxypropylmethyldiethoxysilane and methacryloxypropylmethyldimethoxysilane; and monoalkoxysilane compounds such as methacryloxypropyldimethylethoxysilane and methacryloxypropyldimethylmethoxysilane.

Among others, trialkoxysilane compounds are preferred. Particularly preferred is 3-(trimethoxysilyl)propylmethacrylate.

The composition containing the alkoxysilane compound (3) may further contain an alkoxysilane compound represented by the following general formula (4) (sometimes referred to as “alkoxysilane compound (4)”). In this case, the alkoxysilane compound (4) is hydrolyzed and condensated together with the alkoxysilane compound (3). It is possible to adjust the physical properties such as heat resistance of the hydrolysis condensate by the addition of the alkoxysilane compound (4).

(R⁴)_{w}Si(OR⁵)_{4-w} (4)

In the general formula (4), R⁴ is a methyl group or a phenyl group; when there exist a plurality of R⁴, R⁴ may be of the same kind or different kinds; R⁵ is a methyl group or an ethyl group; when there exist a plurality of R⁵, R⁵ may be of the same kind or different kinds; and w is an integer of 0 to 3.

The alkoxysilane compound (4) may be of a single kind or two or more kinds. Specific examples of the alkoxysilane compound (4) include, but are not limited to, the following: tetraalkoxysilane compounds such as tetramethoxysilane and tetraethoxysilane; trialkoxysilane compounds such as methyltrimethoxysilane, phenyltrimethoxysilane and phenyltriethoxysilane; dialkoxysilane compounds such as dimethyldimethoxysilane, methylphenyldimethoxysilane, dimethyldiethoxysilane, diphenyldiethoxysilane and methylphenyldiethoxysilane; and monoalkoxysilane compounds such as trimethylmethoxysilane.

Among others, trialkoxysilane and dialkoxysilane compounds are preferred. Particularly preferred are phenyltrimethoxysilane and dimethyldiethoxysilane.

In the case of using two or more kinds of the alkoxysilane compounds (4), it is preferable to use trialkoxysilane and dialkoxysilane compounds and, more specifically, phenyltrimethoxysilane and dimethyldiethoxysilane in combination.

In the case where the composition contains not only the alkoxysilane compound (3) but also the alkoxysilane compound (4), there is no particular limitation on the amount of the alkoxysilane compound (4) contained. The alkoxysilane compound (4) may be contained in an amount of 30 to 97 mol % relative to the total amount of the alkoxysilane compound (3) and the alkoxysilane compound (4). The amount of the alkoxysilane compound (4) contained is preferably 50 to 97 mol %, more preferably 80 to 97 mol %, relative to the total amount of the alkoxysilane compound (3) and the alkoxysilane compound (4).

There is no particular limitation on the mass-average molecular weight of the hydrolysis condensate (3). The mass-average molecular weight of the hydrolysis condensate (3) is preferably 500 to 200000, more preferably 500 to 100000. When the mass-average molecular weight of the hydrolysis condensate (3) is 500 or more, the temporary bonding material can sufficiently withstand the after-mentioned processing of the component part. When the mass-average molecular weight of the hydrolysis condensate (3) is 200000 or less, it is easy to maintain the flowability of the composition. The term “mass-average molecular weight” used herein refers to a value determined by gel permeation chromatography on the basis of a calibration curve using polystyrene as a standard material (the same applies to the following).

The following is one example of a production method of the hydrolysis condensate (3). The production method of the hydrolysis condensate (3) is not however limited to the following example.

In one production method, the hydrolysis condensate (3) is obtained by mixing the alkoxysilane compound (3) with water, a polymerization catalyst and, optionally, a reaction solvent and the alkoxysilane compound (4), and subjecting the resulting composition to hydrolysis and condensation. Preferred examples of the polymerization catalyst are acid catalysts such as acetic acid or hydrochloric acid. Preferred examples of the reaction solvent are alcohols. Among others, a lower alcohol is preferred. Particularly preferred is isopropyl alcohol. The reaction temperature is preferably 60 to 80° C. The reaction time may be 6 to 24 hours. After the reaction, the hydrolysis condensate (3) may be purified by extraction, dehydration, solvent removal etc.

[Photopolymerization Initiator]

The photopolymerization initiator is of the type that absorbs light of wavelength 400 nm or more. This photopolymerization initiator generates a radical under irradiation with light of wavelength 400 nm or more and initiates polymerization of the silicone compound (A) under the action of the generated radical. By this polymerization reaction, the silicone compound (A) is polymerized and cured so that the first curable composition loses its flowability and thereby forms a cured film. The cured film is utilized as the first temporary bonding material layer in the temporary bonding material for the temporary bonding of the component part and the substrate. In the case where the temporary bonding material is provided with the first and second temporary bonding material layers, the silicone compound (A) is polymerized, at an interface between the first and second temporary bonding material layers, with a hydrolysis condensate of a photopolymerizable group-containing and hydrolyzable group-containing silicone compound (B) (hereinafter sometimes simply referred to as “silicone compound (B)”) in the second temporary bonding material layer. (The hydrolysis condensate of the silicone compound (B) is sometimes referred to as “hydrolysis condensate (B)”.) By this polymerization reaction, the first and second temporary bonding material layers are bonded together. The hydrolysis condensate (B) of the second temporary bonding material layer may be further polymerized and cured so as to improve the bonding strength between the second temporary bonding material layer and the substrate.

Examples of the photopolymerization initiator includes, but are not limited to, the following: benzophenone, methyl o-benzoylbenzoate, 4-benzoyl-4′-methyldiphenylsulfide, camphorquinone, 2-hydroxy-1-{4-[4-(2-hydroxy-2-methylpropionyl)benzyl]phenyl}-2-methylpropan-1-one, 1-hydroxycyclohexyl phenyl ketone, 1-[4-(2-hydroxyethoxy)-phenyl]2-hydroxy-2-methyl-1-propan-1-one, 2-benzyl-2-dimethylamino-1-(4-morpholinophenyl)-1-butanone, 2-(dimethylamino)-2-[(4-methylphenyl)methyl]-1-[4-(4-morphonyl)phenyl]-1-butanone, a mixture of oxyphenylacetic acid and 2-(2-oxo-2-phenyl acetoxyethoxy)ethyl ester, a mixture of oxyphenylacetic acid and 2-(2-hydroxyethoxy)ethyl ester, 2-methyl-1-(4-methylthiophenyl)-2-morpholinopropan-1-one, bis(2,4,6-trimethylbenzoyl)phenylphosphine oxide and bis(η5-2,4-cyclopentadien-1-yl)-bis[2,6-difluoro-3-(1H-pyrrol-1-yl)phenyl]titanium.

As the photopolymerization initiator, there can also be used Irgacure series available from Chiba Specialty Chemicals Inc., such as Irgacure 127, Irgacure 184, Irgacure 2959, Irgacure 369, Irgacure 379, Irgacure 379EG, Irgacure 907, Irgacure 1700, Irgacure 1800, Irgacure 1850, Irgacure 1870, Irgacure 819, Irgacure 784, Irgacure 4265 and Irgacure 754.

In the present invention, there is no particular limitation on the amount of the photopolymerization initiator contained in the first curable composition. The amount of the photopolymerization initiator contained is preferably 0.01 to 10 mass % relative to the amount of the silicone compound (A). When the amount of the photopolymerization initiator is 0.01 mass % or more, the polymerization and curing reaction of the silicone compound proceeds favorably. There is no need to use the photopolymerization initiator in an amount exceeding 10 mass %.

[Photoacid Generator]

The photoacid generator is of the type that absorbs light of wavelength less than 400 nm. This photoacid generator generates an acid under irradiation with light of wavelength less than 400 nm. As will be explained later, the generated acid reacts with the metal compound of the first curable composition to form a gas or water.

Depending on the material of the component part and the temperature conditions for the processing of the component part in the temporarily bonded state, the photoacid generator may have a 5% weight reduction temperature (T_{d5}) of 250° C. or higher as determined by thermogravimetric analysis. It is preferable that the 5% weight reduction temperature of the photoacid generator is 280° C. or higher. Herein, the term “T_{d5}” refers to a value measured with a thermogravimetric analyzer by heating from 25° C. at a temperature rise rate of 10° C./min under atmospheric pressure (the same applies throughout the present specification). As the thermogravimetric analyzer, there can be used a thermogravimetric/differential thermal analyzer (model: Thermo Plus TG8120, available from Rigaku Corporation).

There is no particular limitation on the kind of the photoacid generator as long as the photoacid generator meets the aforementioned condition. The photoacid generator can be a triarylsulfonate photoacid generator or a nonionic photoacid generator. Examples of the photoacid generator include: ionic compounds such triphenylsulfonium trifluoromethanesulfonate and triphenylsulfonium nonafluoro-n-butanesulfonate (trade name: TPS-109 available from Midori Kagaku Co., Ltd.); nonionic compounds such as those available as NAI-101 (trade name, from Midori Kagaku Co., Ltd.) and NAI-100 (trade name, from Midori Kagaku Co., Ltd.); and those having the following structures.

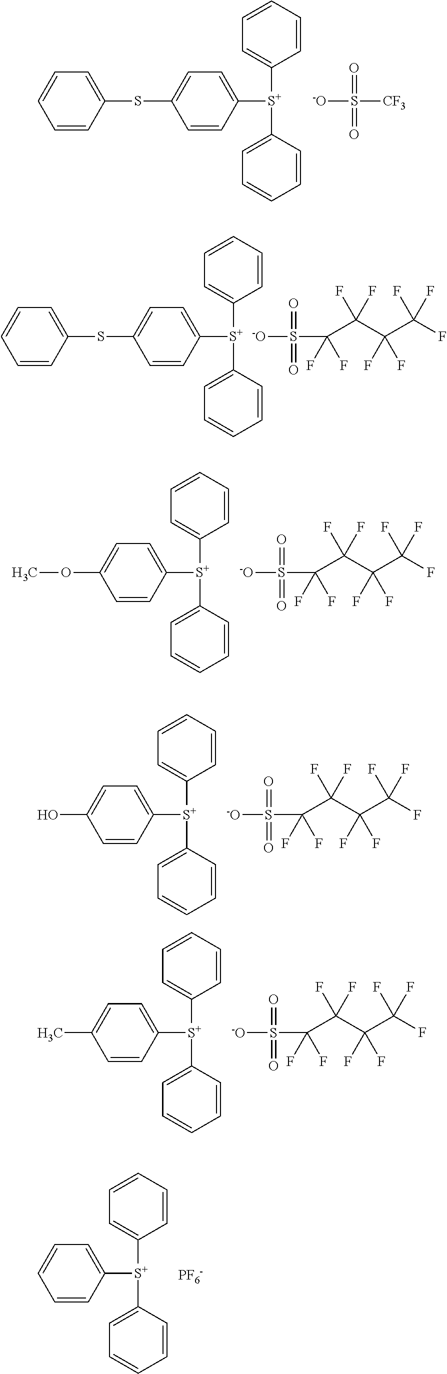

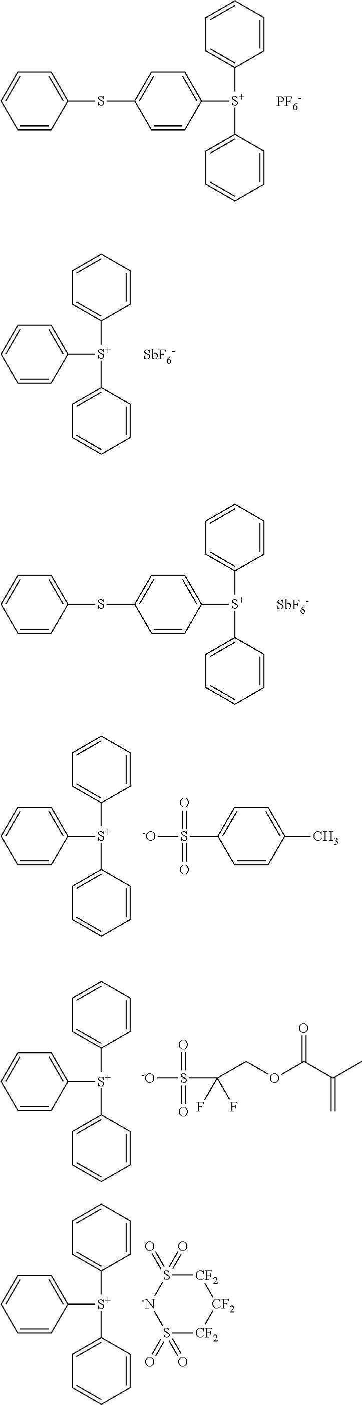

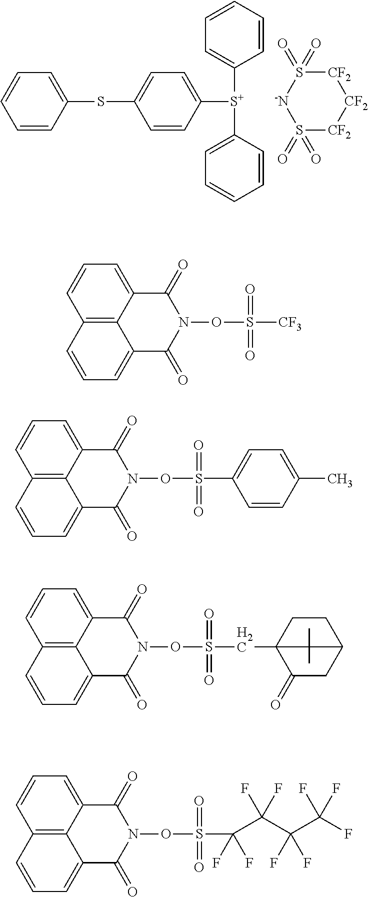

In the present invention, there is no particular limitation on the amount of the photoacid generator contained in the first curable composition. The amount of the photoacid generator contained is preferably 10 mass % or more relative to the amount of the silicone compound (A). When the amount of the photoacid generator is 10 mass % or more, the acid generated from the photoacid generator properly reacts with the after-mentioned metal compound to form a sufficient amount of gas or water for the separation of the component part. The upper limit of the amount of the photoacid generator contained is not particularly limited as long as the first curable composition maintains its flowability. The amount of the photoacid generator contained is preferably 100 mass % or less.

[Metal Compound]

The metal compound is at least one kind selected from the group consisting of metal carbonates, metal oxides and metal hydroxides. Specific examples of the metal compounds include, but are not limited to, the following: metal carbonates such as lithium carbonate (Li₂CO₃, melting point: 723° C.), sodium carbonate (Na₂CO₃, melting point: 851° C.), potassium carbonate (K₂CO₃, melting point: 891° C.), rubidium carbonate (Rb₂CO₃, melting point: 837° C.), cesium carbonate (Cs₂CO₃, melting point: 610° C.), calcium carbonate (CaCO₃, melting point: 825° C.), barium carbonate (BaCO₃, melting point: 811° C.), magnesium carbonate (MgCO₃, melting point: 350° C.), strontium carbonate (SrCO₃, melting point: 1497° C.) and cobalt carbonate (CoCO₃, melting point: 723° C.); metal oxides such as lithium oxide (Li₂O, melting point: 1570° C.), sodium oxide (Na₂O, melting point: 1132° C.), potassium oxide (K₂O, melting point: 350° C.), beryllium oxide (BeO, melting point: 2570° C.), magnesium oxide (MgO, melting point: 2800° C.), calcium oxide (CaO, melting point: 2613° C.), titanium dioxide (TiO₂, melting point: 1870° C.), dichromium trioxide (Cr₂O₃, melting point: 2435° C.), manganese dioxide (MnO₂, melting point: 535° C.), diiron trioxide (Fe₂O₃, melting point: 1566° C.), triiron tetraoxide (Fe₃O₄, melting point: 1597° C.), cobalt oxide (CoO, melting point: 1933° C.), nickel oxide (NiO, melting point: 1984° C.), copper oxide (CuO, melting point: 1201° C.), silver oxide (Ag₂O, melting point: 280° C.), zinc oxide (ZnO, melting point: 1975° C.), aluminum oxide (Al₂O₃, melting point: 2072° C.), tin oxide (SnO, melting point: 1080° C.) and ytterbium oxide (Yb₂O₃, melting point: 2346° C.); metal hydroxides such as lithium hydroxide (LiOH, melting point: 462° C.), sodium hydroxide (NaOH, melting point: 318° C.), potassium hydroxide (KOH, melting point: 360° C.), magnesium hydroxide (Mg(OH)₂, melting point: 350° C.), calcium hydroxide (Ca(OH)₂, melting point: 580° C.), strontium hydroxide (Sr(OH)₂, melting point: 375° C.), barium hydroxide (Ba(OH)₂, melting point: 408° C.) and iron hydroxide (Fe(OH)₂, melting point: 350 to 400° C.).

Among others, it is preferable to use metal compounds of relatively small molecular weight. Preferred are lithium carbonate, sodium carbonate, potassium carbonate, calcium carbonate, magnesium carbonate, lithium oxide, sodium oxide, potassium oxide, beryllium oxide, magnesium oxide, calcium oxide, lithium hydroxide, sodium hydroxide, potassium hydroxide, magnesium hydroxide, calcium hydroxide. Lithium carbonate, sodium carbonate, potassium carbonate, lithium oxide, magnesium oxide, lithium hydroxide and calcium hydroxide are particularly preferred.

The metal oxide easily reacts with the protonic acid generated from the photoacid generator, thereby forming a gas and/or water. In the case of using lithium carbonate or lithium hydroxide as the metal oxide and trifluoromethanesulfonic acid as the protonic acid, for example, carbon dioxide and water are formed as shown in the following reaction schemes.

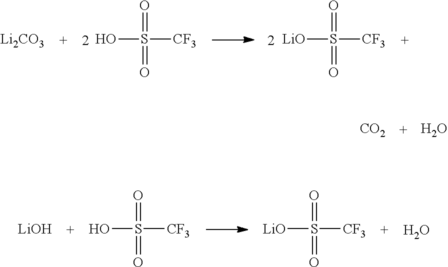

The formation of such a gas and water exerts a stress to separate the component part from the structural unit as will be explained below.

Depending on the material of the component part and the temperature conditions for the processing of the component part in the temporarily bonded state, the metal compound may have a melting point of 250° C. or higher. It is preferable that the melting point of the metal compound is 280° C. or higher.

In the present invention, there is no particular limitation on the amount of the metal compound contained in the first curable composition. The amount of the metal compound contained is preferably 10 mass % or more relative to the amount of the silicone compound (A). When the amount of the metal compound is 10 mass % or more, it is easy to properly bring the metal compound into contact with the acid generated from the photoacid generator so that the above-mentioned gas and/or water can be formed sufficiently. The upper limit of the amount of the metal compound contained is not particularly limited as long as the first curable composition maintains its flowability. The amount of the metal compound contained is preferably 100 mass % or less.

The average particle size of the metal compound is preferably 10 μm or smaller. The lower limit of the average particle size of the metal compound is not particularly limited. Further, the maximum particle size of the metal compound is preferably 30 μm or smaller. The lower limit of the maximum particle size of the metal compound is not also particularly limited. When the average particle size of the metal compound is 10 μm or smaller, the component part can be effectively prevented from damage. When the maximum particle size of the metal compound is 30 μm or smaller, the temporary bonding material can maintain favorable smoothness and uniformity. It is more preferable that: the average particle size of the metal compound is 1 μm or smaller; and the maximum particle size of the metal compound is 5 μm or smaller. When the particle size of the metal compound is in the above range, it is easy to properly bring the metal compound into contact with the acid generated from the photoacid generator so that the above-mentioned gas and/or water can be formed sufficiently. Herein, the “average particle size” of the metal oxide refers to an average value of longer diameters of 20 metal oxide particles arbitrarily selected in an image of the metal oxide as observed by a scanning electron microscope (abbreviation: SEM) with a magnification of 100,000 times.

[Additives]

The first curable compound may contain a compound with a polar group as additive for the purpose of improving or adjusting the bonding between the temporary bonding material and the component part. There is no particular limitation on the polar group. The polar group can be a hydroxyl group, carboxylic acid group, silanol group, phosphoric acid group or the like. Preferred examples of the polar group-containing compound includes those having one or more polar groups and one or more photopolymerizable groups, such as (2-hydroxyethyl)methacrylic acid (abbreviation: HEMA, available from Wako Pure Chemical Industries, Ltd.), pentaerythritol triacrylate (trade name: Biscoat #300, available from Osaka Organic Chemical Industry Ltd.), epoxy acrylate (trade name: Biscoat #540, available from Osaka Organic Chemical Industry Ltd.), tri(2-acryloyloxyethyl)phosphate (trade name: Biscoat 3PA, available from Osaka Organic Chemical Industry Ltd.) and bis(2-methacryloylethyl)phosphate (trade name: KAYAMER PM-2, available from Nippon Kayaku Co., Ltd.). Among others, HEMA is particularly preferred.

Further, the first curable composition may contain a compound with two or more photopolymerizable groups for the purpose of improving the cross-linking density due to the photopolymerizable groups. It is possible to form a stronger cured film by the addition of such a photopolymerizable group-containing compound. Examples of the photopolymerizable group-containing compound includes, but are not limited to, ethylene glycol diacrylate, ethylene glycol dimethacrylate, neopentyl glycol diacrylate, pentaerythritol tetraacrylate, dipentaerythritol hexaacrylate and trimethylolpropane triacrylate (abbreviation: TMPTA). Among other, trimethylolpropane triacrylate is preferred.

In the case of using the additive, the amount of the additive contained is preferably 1 to 30 mass % relative to the amount of the silicone compound (A). When the amount of the additive is 1 mass % or more, the bonding strength or cross-linking density can be effectively improved. There is no need to use the additive in an amount exceeding 50 mass %. The amount of the additive contained is more preferably 10 to 20 mass % relative to the amount of the silicone compound (A).

The first curable composition may contain a filler such as silica or alumina for the purpose of adjusting the thermal expansion coefficient of the first curable composition. The average particle size of the filler is preferably 10 μm or smaller. The lower limit of the average particle size of the filler is not particularly limited. Further, the maximum particle size of the filler is preferably 30 μm or smaller. The lower limit of the maximum particle size of the filler is not particularly limited. When the average particle size of the filler is 10 μm or smaller, the component part can be effectively prevented from damage. When the maximum particle size of the filler is 30 μm or smaller, the temporary bonding material can maintain favorable smoothness and uniformity. It is more preferable that: the average particle size of the filler is 1 μm or smaller; and the maximum particle size of the filler is 5 μm or smaller. Herein, the “average particle size” of the filler refers to an average value of longer diameters of 20 filler particles arbitrarily selected in an image of the filler as observed by a scanning electron microscope (abbreviation: SEM) with a magnification of 100,000 times. The particle shape of the filler is preferably spherical such that the filler can be mixed well with the components of the first curable composition.

[Use of First Curable Composition]

The first curable composition is preferably subjected to mixing or kneading. By the mixing or kneading, the metal compound and the photoacid generator can be favorably dispersed in the first curable composition for improvement in temporary bonding/separation repeatability. The mixing or kneading can be done with the use of various equipment such as stirrer, mortar, homogenizer, roll mill, kneader or the like.

As mentioned above, the first curable composition has flowability. Even when the component part has a surface processed into a fine shape (with protrusions and recesses), the first curable composition can follow such a finely processed surface shape of the component part. It is therefore possible to, when the component part and the substrate are temporarily bonded via the cured film of the first curable composition by irradiation with light of wavelength 400 nm or more, prevent an air bubble from being trapped between the cured composition film and the temporary bonding surface of the component part and allow the cured composition film to withstand the subsequent processing of the component part.

2. Temporary Bonding Material

The temporary bonding material according to the present invention has at least the cured film of the first curable composition as the first temporary bonding material layer.

The cured film of the first curable composition is obtained by applying a coating film of the first curable composition to the component part or the substrate and irradiating the applied coating film with light of wavelength 400 nm or more.

Since the first curable composition has flowability, it is feasible to apply the first curable composition to the component part or the substrate without dissolving the first curable composition in a solvent. In this case, heating treatment such as pre-baking may be omitted. It is alternatively feasible to use a solvent for the application of the first curable composition to the component part or the substrate. In the case of using the solvent, the first curable composition is applied in the form of a solution in which the first curable composition is dissolved in the solvent (hereinafter sometimes referred to as “solution (A)”) to the component part or the substrate. The coating film of the first curable composition is formed by, after the application of the solution (A), pre-baking the applied coating according to the vaporization conditions of the solvent and thereby vaporizing the solvent. The pre-baked coating film is irradiated with light of wavelength 400 nm or more. Under this light irradiation, the coating film of the first curable composition is cured to the cured film (as the first temporary bonding material layer) so that the component part and the substrate are bonded to each other via the cured film.

The kind of the solvent used can be selected as appropriate depending on the solubility of the first curable composition and the materials of the component part and substrate. Examples of the solvent include, but are not limited to, isopropyl alcohol, propylene glycol methyl ether acetate (abbreviation: PGMEA), propylene glycol monomethyl ether (abbreviation: PGME), methyl isobutyl ketone (abbreviation: MIBK) and methyl ethyl ketone (abbreviation: MEK). These solvents may be used solely or in combination of two or more kinds thereof.

There is no particular limitation on the method for application of the solution (A) as long as the solution (A) can be applied to form a smooth thin film. For example, it is feasible to adopt a spin coating method, a dip coating method, a bar coating method, a roll coating method, a die coating method or a slit coating method as the application method of the solution (A).

As the method of direct application of the first curable composition without the use of the solvent, it is feasible to adopt a dispenser or screen printing method etc. in addition to the above-mentioned application method.

The temporary bonding material according to the present invention is usable as a wafer-processing temporary bonding material as will be explained layer.

[Second Temporary Bonding Material Layer Formed as Film of Second Curable Composition]

The temporary bonding material according to the present invention may have the second temporary bonding material layer. The second temporary bonding layer is formed of a second curable composition containing at least the hydrolysis condensate of the photopolymerizable group-containing and hydrolyzable group-containing silicone compound (B) (sometimes referred to as “silicone compound (B)”).

The second temporary bonding material layer may be formed as a film on the film layer of the first curable composition or on the substrate for the temporary bonding of the component part and the substrate.

For the temporary bonding of the component part and the substrate, the second temporary bonding material layer can be, and is preferably, formed in advance on the substrate by applying a coating film of the second curable composition to the substrate. It is feasible to apply the second curable composition in the form of a solution in which the second curable composition is dissolved in a solvent (hereinafter sometimes referred to as “solution (B)”) to the substrate. After the application of the solution (B), the coating film is pre-baked according to the vaporization conditions of the solvent to vaporize the solvent and thereby form the second temporary bonding material layer on the substrate. The kind of the solvent used can be selected as appropriate depending on the solubility of the second curable composition and the materials of the component part and substrate. Examples of the solvent include, but are not limited to, propylene glycol 1-monomethyl 2-ether acetate (abbreviation: PGMEA) and propylene glycol monomethyl ether (abbreviation: PGME). These solvents may be used solely or in combination of two or more kinds thereof. After the pre-baking, the film of the second curable composition may be cured by further heat treatment at 80 to 250° C. in order to ensure the bonding strength of the second temporary bonding material layer to the substrate and the heat resistance of the second temporary bonding material layer.

There is no particular limitation on the method for application of the solution (B) as long as the solution (B) can be applied to form a smooth thin film. For example, it is feasible to adopt a spin coating method, a dip coating method, a bar coating method, a roll coating method, a die coating method or a slit coating method as the application method of the solution (B). Among others, preferred is a spin coating method commonly used for semiconductor processing and capable of attaining coating surface smoothness.

There is no particular limitation on the thickness of the second temporary bonding material layer as long as the second temporary bonding material layer can withstand the respective processing operations, i.e., the temporary bonding of the component part and the substrate, the processing of the component part and the separation of the component part and the substrate in the present invention. The thickness of the temporary bonding material layer varies depending on the kinds of the component part and the substrate and the kind of the processing. In general, the thickness of the temporary bonding material layer is preferably 0.5 to 500 μm, more preferably 0.5 to 200 μm. Further, the total thickness of the first and second bonding material layers of the temporary bonding material is preferably 1 to 1000 μm, more preferably 1 to 400 μm.

The second curable composition contains at least the hydrolysis condensate of the silicone compound (B) (sometimes referred to as “hydrolysis condensate (B)”).

[Hydrolysis Condensate (B)]

The photopolymerizable group of the silicone compound (B) refers to a functional group capable of polymerizing with the photopolymerizable group-containing silicone compound (A) or the other polymerizable group-containing compound under light irradiation. Examples of the photopolymerizable group include, but are not limited to, an acryloyl group and a methacryloyl group. Examples of the hydrolyzable group of the silicone compound (B) include an alkoxy group and a chlorine atom.

Depending on the material of the component part and the temperature conditions for the processing of the component part in the temporarily bonded state, the silicone compound (B) may have a 5% weight reduction temperature (T_{d5}) of 250° C. or higher as determined by thermogravimetric analysis. It is preferable that the 5% weight reduction temperature of the silicone compound (B) is 280° C. or higher.

There is no particular limitation on the mass-average molecular weight of the hydrolysis condensate (B). The mass-average molecular weight of the hydrolysis condensate (B) is preferably 500 to 200000, more preferably 500 to 100000. When the mass-average molecular weight of the hydrolysis condensate (B) is 500 or more, the temporary bonding material can sufficiently withstand the after-mentioned processing of the component part. When the mass-average molecular weight of the hydrolysis condensate (B) is 200000 or less, it is easy to remove the temporary bonding material after the separation of the component part and the substrate.

The hydrolysis condensate (B) can be, but is not limited to, a hydrolysis condensate obtained by hydrolysis and condensation of an alkoxysilane compound represented by the following general formula (5) (sometimes referred to as “alkoxysilane compound (5)”).

(R⁶)ₛSi(OR⁷)₄₋ₛ (5)

In the general formula (5), R⁶ is an organic moiety having at least one kind of group selected from the group consisting of acryloyl and methacryloyl groups; when there exist a plurality of R⁶, R⁶ may be of the same kind or different kinds; R⁷ is a methyl group or an ethyl group; when there exist a plurality of R⁷, R⁷ may be of the same kind or different kinds; and s is an integer of 1 to 3.

Examples of the organic moiety having at least one selected from the group consisting of acryloyl and methacryloyl groups include, but are not limited to, methacryloyloxyalkyl groups and acryloyloxyalkyl groups.

The alkoxysilane compound (5) may be of a single kind or two or more kinds. Examples of the alkoxysilane compound (5) are the same as those listed above as examples of the alkoxysilane compound (3). Among others, trialkoxysilane and dialkoxysilane compounds are preferred. Particularly preferred is 3-(trimethoxysilyl)propylmethacrylate.

The hydrolysis condensate (B) can alternatively be a hydrolysis condensate obtained by hydrolysis and condensation of at least one kind of alkoxysilane compound (5) and at least one kind of alkoxysilane compound represented by the following general formula (6) (sometimes referred to as “alkoxysilane compound (6)”). It is possible to adjust the physical properties such as heat resistance of the hydrolysis condensate by the combined use of the alkoxysilane compound (5) and the alkoxysilane compound (6).

(R⁸)ₜSi(OR⁹)₄₋ₜ (6)

In the general formula (6), R⁸ is a methyl group or a phenyl group; when there exist a plurality of R⁸, R⁸ may be of the same kind or different kinds; R⁹ is a methyl group or an ethyl group; when there exist a plurality of R⁹, R⁹ may be of the same kind or different kinds; and t is an integer of 0 to 3.

The alkoxysilane compound (6) may be of a single kind or two or more kinds. Examples of the alkoxysilane compound (6) are the same as those listed above as examples of the alkoxysilane compound (4). Among others, trialkoxysilane and dialkoxysilane compounds are preferred. Particularly preferred are phenyltrimethoxysilane and dimethyldiethoxysilane.

In the case of using two or more kinds of the alkoxysilane compounds (6), it is preferable to use trialkoxysilane and dialkoxysilane compounds and, more specifically, phenyltrimethoxysilane and dimethyldiethoxysilane in combination.

In the case of using the alkoxysilane compound (6), there is no particular limitation on the amount of the alkoxysilane compound (6) used. The amount of the alkoxysilane compound (6) used is preferably 3 to 50 mol %, more preferably 3 to 20 mol %, relative to the total amount of the alkoxysilane compound (5) and the alkoxysilane compound (6).

The following is one example of a production method of the hydrolysis condensate (B). The production method of the hydrolysis condensate (B) is not however limited to the following example.

In one production method, the hydrolysis condensate (B) is obtained by mixing the alkoxysilane compound (5) with water, a polymerization catalyst and, optionally, a reaction solvent and the alkoxysilane compound (6), and subjecting the resulting composition to hydrolysis and condensation. Preferred examples of the polymerization catalyst are acid catalysts such as acetic acid or hydrochloric acid. Preferred examples of the reaction solvent are alcohols. Among others, a lower alcohol is preferred. Particularly preferred is isopropyl alcohol. The reaction temperature is preferably 60 to 80° C. The reaction time may be 6 to 24 hours. After the reaction, the hydrolysis condensate (B) may be purified by extraction, dehydration, solvent removal etc.

[Photopolymerization Initiator]

The second curable composition may contain a photopolymerization initiator. It is expected that, by the addition of the photopolymerizable initiator, chemical bonds are efficiently formed over a wide range between the first curable composition and the second temporary bonding material layer under irradiation with light of wavelength 400 nm or more during the temporary bonding step for the strong bonding of the first and second temporary bonding material layers. Examples of the photopolymerization initiator contained in the second curable composition are the same as those contained in the first curable composition. The photopolymerization initiator can be contained in the second curable composition in an amount of 0.01 to 5 mass % relative to the amount of the hydrolysis condensate (B).

[Filler]

The second curable composition may contain a filler such as known antioxidant or silica for further improvement in heat resistance.

3. Structural Unit

The structural unit according to the present invention has the component part and the substrate temporarily bonded to each other via the temporary bonding material. The component part and the substrate are bonded to each other according to the after-mentioned temporary bonding method.

[Component Part]

There is no particular limitation on the component part. Examples of the component part include quartz members, glass members, plastic members and semiconductor wafers. Consequently, the temporary bonding method according to the present invention is applicable as a temporary bonding technique for the processing of quartz oscillators, glass lens, plastic lens, optical discs and semiconductor wafers.

In the case of using the semiconductor wafer as the component part, the semiconductor wafer can be a silicon wafer, a germanium wafer, a gallium-arsenide wafer, a gallium-phosphorus wafer, a gallium-arsenide-aluminum wafer, a gallium nitride wafer or a silicon carbide wafer. The semiconductor wafer may be partially subjected in advance to polishing, grinding or other processing and may be covered with a protective film (permanent film).

The surface of the component part may be formed with a fine structure (protrusion/recess structure). The first curable composition used in the temporary bonding method of the component part and the substrate according to the present invention has flowability. Even when the surface of the component part is formed with a fine structure (protrusion/recess structure), the first curable composition can follow such a fine surface structure of the component part. It is therefore possible to, when the component part and the substrate are temporarily bonded via the temporary bonding material by curing the first curable composition, prevent an air bubble from being trapped between the component part and the bonding material and allow the bonding material to withstand the subsequent processing of the component part. The temporary bonding method according to the present invention is thus particularly useful for the temporary bonding of the component part and the substrate in the case where the surface of the component part is formed with a fine structure (protrusion/recess structure).

There is no particular limitation on the thickness of the component part. In the case of using the semiconductor wafer as the component part, for example, the thickness of the component part is typically 200 to 1000 μm, more typically 625 to 775 μm.

[Substrate]

There is no particular limitation on the material of the substrate. In terms of the efficiency of irradiation of the temporary bonding surface with light of wavelength 400 nm or more during the temporary bonding step and the efficiency of irradiation of the temporary bonding surface with light of wavelength less than 400 nm during the separation step, the material of the substrate is preferably of the kind that allows the irradiation light to pass therethrough. By the use of such a substrate material, it is possible to properly irradiate the temporary bonding surface with the irradiation light through the substrate even when the irradiation light is emitted from the non-temporary bonding surface side of the substrate. Examples of the substrate include, but are not limited to, quartz substrates, glass substrates and plastic substrates. The material of the substrate can be selected as appropriate depending on the type of the light source used.

In the case of using the glass substrate as the substrate, the glass substrate can be of soda-lime glass, non-alkaline glass, borosilicate glass, aluminosilicate glass, fused quartz glass or synthetic quartz glass. The glass substrate may contain an alkali element in an amount of 1 mass % or less. Examples of such a glass substrate are a non-alkaline glass substrate, a fused quartz glass substrate and a synthetic quartz glass substrate. Among others, a non-alkaline glass substrate is preferred in terms of the availability.

In the case of using the alkali element-containing glass substrate as the substrate, it is preferable to form a barrier film on a glass surface of the substrate before the use of the substrate. There is no particular limitation on the material of the barrier film as long as the barrier film exhibits a barrier function. In terms of the bonding strength, SiO₂ is preferred as the material of the barrier film. The barrier film can be formed by a vapor deposition method, a sputtering method, a thermal-decomposition film forming method, a sol-gel method etc.

For the purpose of improving the bonding strength between the substrate and the temporary bonding material, it is preferable to treat in advance the surface of the substrate for bonding with the temporary bonding material by polishing treatment such as ceria polishing, zirconia polishing or alumina polishing, cleaning treatment with an acidic aqueous solution, cleaning treatment with a basic aqueous solution, cleaning treatment with a surfactant, cleaning treatment with ozone water, UV ozone irradiation treatment, plasma irradiation treatment or a combination thereof. By such treatment, the surface of the substrate is made hydrophilic for the strong bonding with the temporary bonding material.

The material of the substrate can be selected as appropriate depending on the material of the component part. In the case where the material of the component part is of the kind that allows light of wavelength 400 nm or more to pass therethrough, for example, it is preferable that the material of the substrate is of the kind that allows at least light of wavelength less than 400 nm to pass therethrough. In the case where the material of the component part is of the kind that allows light of wavelength less than 400 nm to pass therethrough, it is preferable that the material of the substrate is of the kind that allows at least light of wavelength 400 nm or more to pass therethrough.

4. Temporary Bonding Method of Component Part and Substrate

The temporary bonding method of the component part and the substrate according to the present invention (hereinafter sometimes simply referred to as “temporary bonding method according to the present invention”) includes at least the following first to fourth steps.

First step: stacking the component part and the substrate together with the uncured temporary bonding material, which has at least the layer of the first curable composition, being interposed therebetween.
Second step: irradiating the uncured temporary bonding material with light of wavelength 400 nm or more, thereby curing the uncured temporary bonding material to form the structural unit in which the component part and the substrate are temporarily bonded to each other via the cured temporary bonding material.
Third step: processing the component part of the structural unit.
Fourth step: after the processing step, separating the component part from the structural unit by irradiating the cured temporary bonding material of the structural unit with light of wavelength less than 400 nm.

In terms of the cost efficiency for mass-production, it is preferable to remove a residue of the cured temporary bonding material from the substrate and recycle the substrate. Namely, the temporary bonding method of the component part and the substrate according to the present invention may further include the following sixth and seventh steps.

Sixth step: after the separation step, removing the residue of the cured temporary bonding material from the substrate.
Seventh step: recycling the substrate obtained by the sixth step in the first step.

The temporary bonding method of the component part and the substrate according to the present invention may include the following fifth step, as needed, after the fourth step due to the fact that the cured temporary bonding material does not remain or remains in a slight amount on the component part after the fourth step.

Fifth step: removing a residue of the cured temporary bonding material from the component part.

[First Step]

In the first step, the component part and the substrate are stacked together via the uncured temporary bonding material. The uncured temporary bonding material has at least the layer of the first curable composition according to the present invention. The uncured temporary bonding material may also have the second temporary bonding material layer. In the case where the uncured temporary bonding material has the second temporary bonding material layer, the layer of the first curable composition is arranged in contact with the component part and the second temporary bonding material layer; and the second temporary bonding material layer is arranged in contact with the layer of the first curable composition and the substrate. In other words, the component part, the layer of the first curable composition, the second temporary bonding material layer and the substrate are arranged in this order.

[Second Step]

In the second step, the uncured temporary bonding material is irradiated with light of wavelength 400 nm or more and thereby cured to form the structural unit in which the component part and the substrate are temporarily bonded to each other via the cured temporary bonding material.

Under irradiation with light of wavelength 400 nm or more, the photopolymerization initiator of the first curable composition layer of the uncured temporary bonding material generates a radical and initiates polymerization reaction of the silicone compound (A) of the first curable composition layer. By this reaction, the silicone compound (A) undergoes polymerization and curing. The uncured temporary bonding material is consequently cured so that the component part and the substrate are bonded together via the cured temporary bonding material. In the case where the uncured temporary bonding material has the second temporary bonding material layer, the polymerization reaction of the silicone compound (A) and the hydrolysis condensate (B) also occurs at the interface between the layer of the first curable composition and the second temporary bonding material layer. By this polymerization reaction, the first and second temporary bonding material layers are bonded together. The hydrolysis condensate (B) of the second temporary bonding material layer may be further polymerized and cured so as to improve the bonding strength between the second temporary bonding material layer and the substrate.

There is no particular limitation on the method for irradiation the temporary bonding material forming layer with light of wavelength 400 nm or more. As to the light emission direction, the light can be directly emitted to the uncured temporary bonding material. In terms of the light irradiation efficiency, it is preferable to use the component part or substrate of the type that allows light of wavelength 400 nm or more to pass therethrough as mentioned above and emit the light from the side of the component part or substrate to the uncured temporary bonding material. There is no particular limitation on the light irradiation time as long as the component part and the substrate are bonded to each other via the temporary bonding material and, in the case where the uncured temporary bonding material has the second temporary bonding material layer, the first and second bonding material layer are bonded to each other. The light irradiation time is generally of the order of 5 seconds to 10 minutes and is adjusted as appropriate. In terms of the efficiency, it is preferable that the light irradiation time is shorter. There is no particular limitation on the light source as long as the light source emits light of wavelength 400 nm or more. It is preferable that the light emitted from the light source contains less or no light of wavelength less than 400 nm. Examples of such a light source include, but are not limited to, a blue LED with a center emission wavelength of 405 nm, a LED with a center emission wavelength of 420 nm, a LED with a center emission wavelength of 465 nm and a LED with a center emission wavelength of 595 nm. There is also no particular limitation on the integrated amount of light of wavelength 400 nm or more. The integrated light amount is generally 1 to 300000 mJ/cm², preferably 10 to 30000 mJ/cm². Herein, the integrated light amount can be measured with e.g. a commercially available light intensity meter (main body model: UIT-201, photodetector model: UVD-405PD etc., from Ushio Inc.).

[Third Step]

In the third step, the component part of the structural unit obtained by the second step is processed. There is no particular limitation on the kind of the processing performed in this step. Any desired processing is performed on the component part depending on the kind of the component part and the purpose of use of the component part. In the case of processing a glass, optical lens, optical component part, optical device, prism or semiconductor package as the component part, it is feasible to perform desired machining such as cutting, polishing, grinding, surface protection or drilling on the component part. For example, the processing of the semiconductor wafer can be thickness reduction of the semiconductor wafer by grinding or polishing for the production of a thin wafer, formation of electrodes on the semiconductor wafer, formation of metal wirings on the semiconductor wafer, formation of a protective film on the semiconductor wafer and the like. Specific examples of the processing of the semiconductor wafer include known processing operations such as metal sputtering for formation of electrodes, wet etching of a metal sputtering layer, pattern formation by application, exposure and developing of a resist for formation of a metal wiring forming mask, resist removal, dry etching, metal plating formation, silicon etching for TSV formation, formation of an oxide film on silicon surface and the like.

[Fourth Step]

In the fourth step, the processed component part is separated from the structural unit by irradiating the cured temporary bonding material of the structural unit with light of wavelength less than 400 nm. For the separation of the component part, the cured temporary bonding material is irradiated with light of wavelength less than 400 nm under a predetermined temperature condition for a predetermined time period. Under such light irradiation, the photoacid generator of the first temporary bonding material layer generates an acid to form a gas or water by reaction of the generated acid with the metal compound of the first temporary bonding material layer. By this gas/water formation reaction, there arises an internal stress to separate the processed component part from the structural unit. As a consequence, the processed component part is easily separated from the structural unit. There is no particular limitation on the method for detachment of the processed component part from the structural unit after the light irradiation. For example, it is feasible to detach the processed component part from the structural unit by sliding the component part and the substrate in horizontally opposite directions or by, while fixing one of the component part and the substrate in a horizontal orientation, lifting up the other of the component part and the substrate at a certain angle from the horizontal orientation.

There is no particular limitation on the temperature condition for the irradiation with light of wavelength less than 400 nm as long as the workpiece obtained by processing the component part in the third step is not adversely affected by the light irradiation. It is preferable to perform the light irradiation at 100° C. or higher so as to allow easier separation of the component part by volatilization the generated water. Alternatively, it is feasible to separate the component part by stimulating the chemical reaction under heating after the irradiation with light of wavelength less than 400 nm. In this case, the component part is separated by e.g. additional heating after irradiating the cured temporary bonding material with light of wavelength less than 400 nm at room temperature. In any of the above cases, the processed component part is easily separated from the structural unit by the action of internal stress due to the gas/water formation. As to the light emission direction, the light can be directly emitted to the cured temporary bonding material. In terms of the light irradiation efficiency, it is preferable to use the component part or substrate of the type that allows light of wavelength less than 400 nm to pass therethrough as mentioned above and emit the light from the side of the component part or substrate to the cured temporary bonding material. There is no particular limitation on the light irradiation time as long as the processed component part is separated from the structural unit. The light irradiation time is generally of the order of 5 seconds to 10 minutes and is adjusted as appropriate. In terms of the efficiency, it is preferable that the light irradiation time is shorter. There is no particular limitation on the light source as long as the light source emits light of wavelength less than 400 nm. Examples of such a light source include known ultraviolet lamps such as a low-pressure mercury lamp, a high-pressure mercury lamp, a short-arc discharge lamp and an ultraviolet light-emitting diode. Depending on the integrated light amount and wavelength suitable for the photoacid generator, a high-pressure mercury lamp or metal halide lamp categorized as a high-pressure discharge lamp, or a xenon lamp categorized as a short-arc discharge lamp, can be used. There is also no particular limitation on the integrated amount of light of wavelength less than 400 nm. The integrated light amount is generally 300 J/cm² or less, preferably 30 mJ/cm² or less. Herein, the integrated light amount can be measured with e.g. a commercially available light intensity meter (main body model: UIT-201, photodetector model: UVD-365PD etc., from Ushio Inc.).

[Fifth Step]

In the temporary bonding method according to the present invention, there remains no or almost no residue of the cured temporary bonding material on the processed component part; and all or almost all of the cured temporary bonding material remains adhered to the substrate. The residue of the cured temporary bonding material, if remains in a small amount on the processed component part, is removed. It is feasible to remove the residue of the cured temporary bonding material by e.g. washing the processed component part. The processed component part can be washing with any washing liquid that dissolves the residue of the cured temporary bonding material without adversely affecting the processed component part (workpiece). In the processing of the semiconductor wafer, for example, the following organic solvents are usable as the washing liquid: isopropanol, PGMEA, PGME, MEK, hexane, toluene, N-methylpyrrolidone and acetone. These organic solvents can be used solely or in combination of two or more kinds thereof. The organic solvent may be used as a mixed solution with a base or an acid. The base or acid may be added in the form of an aqueous solution. Further, a known surfactant may be added to the organic solvent.

Examples of the washing method include paddle washing with the organic solvent, spray washing, immersion washing in a washing bath or the like. The washing temperature is generally 20 to 100° C., preferably higher than or equal to 20° C. and lower than 50° C. The processed component part may be obtained by, after dissolving the cured temporary bonding material in the dissolution liquid, rinsing the component part with water or alcohol as needed and drying the component part.

[Sixth Step]

After the fourth step, almost all or all of the cured temporary bonding material remains adhered to the substrate. In the sixth step, the residue of the cured temporary bonding material is removed from the substrate. It is feasible to remove the residue of the cured temporary bonding material from the substrate by e.g. washing the substrate. There is no particular limitation on the method for washing of the substrate as long as the residue of the cured temporary bonding material is removed from the substrate. In the case where the substrate after the removal of the bonding material residue is recycled in the first step, it is preferable to adopt any washing method that does not adversely affect the substrate. In the case of using a glass substrate, the washing method described for the above fifth step or the after-mentioned base washing method or acid washing method can be adopted. The base washing method or acid washing method is preferred.

(Base Washing Method)

In the base washing method, the substrate is washed with a mixed washing liquid of a tetraalkylammonium hydroxide with an alkyl carbon number of 1 to 5, an alcohol with a carbon number of 1 to 5 and N-methylpyrrolidone. The composition ratio of the mixed washing liquid is preferably in the range of tetraalkylammonium hydroxide:N-methylpyrrolidone=1 to 20:20 to 98:1 to 79. Specific examples of the base washing method include an immersion washing method in which the substrate is immersed in an immersion bath of the mixed washing liquid, a showering method in which the mixed washing liquid is poured in shower form, spray form and/or jet form, a scrub washing method using a sponge, brush etc., an ultrasonic washing method in which an ultrasonic wave is applied to the mixed washing liquid for improvement in washing efficiency, a bubble washing method and the like. The temperature of the mixed washing liquid during contact with the substrate is preferably 20 to 120° C., more preferably 40 to 100° C.

(Acid Washing Method)

In the acid washing method, the substrate is washed with a washing liquid containing sulfuric acid and hydrogen peroxide (referred to as “SPM washing”) or washed with a mixed washing liquid of hydrochloric acid, hydrogen peroxide and ultrapure water (referred to as “HPM washing”), washed with an aqueous nitric acid solution (referred to as “nitric acid washing”), washed with water and then dried.

The SPM washing is performed by heating the washing liquid containing sulfuric acid and hydrogen peroxide. There is no particular limitation on the washing conditions. The composition of the washing liquid is generally in the range of sulfuric acid:hydrogen peroxide=4:1 to 8:1 in volume ratio. The adequate washing temperature range is 80 to 150° C.

The HPM washing is performed by heating the washing the mixed washing liquid of hydrochloric acid, hydrogen peroxide and ultrapure water. There is no particular limitation on the washing conditions. The composition of the mixed washing liquid is generally in the range of hydrochloric acid:hydrogen peroxide:ultrapure water=1:1:5 to 1:4:10 in volume ratio. The adequate washing temperature range is 80 to 100° C.

The nitric acid washing is performed by using the aqueous nitric acid solution with a nitric acid concentration of preferably 1 to 60 mass %, more preferably 10 to 40 mass %. There is no particular limitation on the washing temperature. The washing temperature is preferably 20 to 100° C., more preferably 40 to 90° C. In this nitric washing, any components that cannot be removed by the SPM washing or HPM washing are removed from the substrate surface by the oxidizing power of the nitric acid. By performing the nitric acid washing subsequent to the SPM washing or HPM washing, chlorine ions derived from the hydrochloric acid and remaining in a small amount on the substrate surface are also removed.

[Seventh Step]

The substrate obtained by the sixth step can be recycled in the first step.

5. Wafer-Processing Temporary Bonding Material

There is provided according to the present invention a wafer-processing temporary bonding material for temporarily bonding a wafer, which has a front surface with a circuit forming area and a back surface to be processed, to a support medium by being interposed between the front surface of the wafer and the support medium. More specifically, the above-mentioned temporary bonding material is usable as the wafer-processing temporary bonding material in the present invention. Examples of the wafer are the same kinds of semiconductor wafers as those listed above as examples of the component part. Examples of the support medium are the same kinds of glass substrates as those listed above as examples of the substrate.

6. Temporary Bonding Method of Wafer and Support Medium

There is also provided according to the present invention a method for temporarily bonding a wafer, which has a front surface with a circuit forming area and a back surface to be processed, to a support medium, including at least the following steps (a) to (d).

Step (a): stacking the wafer and the support medium together with the uncured wafer-processing temporary bonding material, which has at least the layer of the first curable composition, being interposed therebetween.
Step (b): irradiating the uncured wafer-processing temporary bonding material with light of wavelength 400 nm or more, thereby curing the uncured wafer-processing temporary bonding material to form a wafer-processing structural unit in which the front surface of the wafer is temporarily bonded to the support medium via the cured wafer-processing temporary bonding material.
Step (c): processing the back surface of the wafer of the wafer-processing structural unit.
Step (d): after the processing step, separating the wafer from the wafer-processing structural unit by irradiating the cured wafer-processing temporary bonding material of the wafer-processing structural unit with light of wavelength less than 400 nm.

In terms of the cost efficiency for mass-production, it is preferable to remove a residue of the cured wafer-processing temporary bonding material from the support medium and recycle the support medium. Namely, the temporary bonding method of the wafer and the support medium according to the present invention may further include the following steps (f) and (g).

Step (f): after the separation step, removing the residue of the cured wafer-processing temporary bonding material from the support medium.
Step (g): recycling the support medium obtained by the step (f) in the step (a).

The temporary bonding method of the wafer and the support medium according to the present invention may include the following step (e), as needed, after the step (d) due to the fact that the cured wafer-processing temporary bonding material does not remain or remains in a slight amount on the wafer after the step (d).

Step (e): removing the residue of the cured wafer-processing temporary bonding material from the wafer.

The respective steps will be explained below in detail.

[Step (a)]

In the step (a), the wafer and the support medium are stacked together via the uncured wafer-processing temporary bonding material. The uncured wafer-processing temporary bonding material has at least the layer of the first curable composition according to the present invention. The layer of the first curable composition is arranged in contact with the front surface of the wafer and the support medium. The uncured wafer-processing temporary bonding material may also have the second temporary bonding material layer. In the case where the uncured wafer-processing temporary bonding material has the second temporary bonding material layer, the layer of the first curable composition is arranged in contact with the front surface of the wafer and the second temporary bonding material layer; and the second temporary bonding material layer is arranged in contact with the layer of the first curable composition and the support medium. In other words, the wafer, the layer of the first curable composition, the second temporary bonding material layer and the support medium are arranged in this order.

[Step (b)]

In the step (b), the uncured wafer-processing temporary bonding material is irradiated with light of wavelength 400 nm or more and thereby cured to form the wafer-processing structural unit in which the front surface of the wafer and the support medium are temporarily bonded to each other via the cured wafer-processing temporary bonding material.

The step (b) can be performed in the same manner as in the second step. The explanations of the second step are applicable to the step (b), assuming that the uncured temporary bonding material, the cured temporary bonding material, the component part, the substrate and the structural unit correspond to the uncured wafer-processing temporary bonding material, the cured wafer-processing temporary bonding material, the front surface of the wafer, the support medium and the wafer-processing structural unit, respectively.

[Step (c)]

In the step (c), the back surface of the wafer of the wafer-processing structural unit obtained by the step (b) is processed. There is no particular limitation on the kind of the processing performed in this step. Any desired processing is performed on the back surface of the wafer. For example, the processing of the wafer can be thickness reduction of the wafer by grinding or polishing for the production of a thin wafer, formation of electrodes on the wafer, formation of metal wirings on the wafer, formation of a protective film on the wafer and the like. Specific examples of the processing of the wafer include known processing operations such as metal sputtering for formation of electrodes, wet etching of a metal sputtering layer, pattern formation by application, exposure and developing of a resist for formation of a metal wiring forming mask, resist removal, dry etching, metal plating formation, silicon etching for TSV formation, formation of an oxide film on silicon surface and the like.

[Step (d)]

In the step (d), the processed wafer is separated from the wafer-processing structural unit by irradiating the cured wafer-processing temporary bonding material of the wafer-processing structural unit with light of wavelength less than 400 nm. For the separation of the wafer, the cured wafer-processing temporary bonding material is irradiated with light of wavelength less than 400 nm under a predetermined temperature condition for a predetermined time period. Under such light irradiation, the photoacid generator of the first temporary bonding material layer generates an acid to form a gas or water by reaction of the generated acid with the metal compound of the first temporary bonding material layer. By this gas/water formation reaction, there arises an internal stress to separate the processed wafer from the wafer-processing structural unit. As a consequence, the processed wafer is easily separated from the wafer-processing structural unit. There is no particular limitation on the method for detachment of the processed wafer from the wafer-processing structural unit after the light irradiation. For example, it is feasible to detach the processed wafer from the wafer-processing structural unit by sliding the wafer and the support medium in horizontally opposite directions or by, while fixing one of the wafer and the support medium in a horizontal orientation, lifting up the other of the wafer and the support medium at a certain angle from the horizontal orientation.

There is no particular limitation on the temperature condition for the irradiation with light of wavelength less than 400 nm as long as the workpiece obtained by processing the back surface of the wafer in the step (c) is not adversely affected by the light irradiation. It is preferable to perform the light irradiation at 100° C. or higher so as to allow easier separation of the wafer by volatilization the generated water. Alternatively, it is feasible to separate the wafer by stimulating the chemical reaction under heating after the irradiation with light of wavelength less than 400 nm. In this case, the wafer is separated by e.g. additional heating after irradiating the cured wafer-processing temporary bonding material with light of wavelength less than 400 nm at room temperature. In any of the above cases, the processed wafer is easily separated from the wafer-processing structural unit by the action of internal stress due to the gas/water formation. As to the light emission direction, the light can be directly emitted to the cured wafer-processing temporary bonding material. In terms of the light irradiation efficiency, it is preferable to use the support medium of the type that allows light of wavelength less than 400 nm to pass therethrough and emit the light from the side of the support medium to the cured wafer-processing temporary bonding material. There is no particular limitation on the light irradiation time as long as the processed wafer is separated from the wafer-processing structural unit. The light irradiation time is generally of the order of 5 seconds to 10 minutes and is adjusted as appropriate. In terms of the efficiency, it is preferable that the light irradiation time is shorter. There is no particular limitation on the light source as long as the light source emits light of wavelength less than 400 nm. Examples of such a light source include known ultraviolet lamps such as a low-pressure mercury lamp, a high-pressure mercury lamp, a short-arc discharge lamp and an ultraviolet light-emitting diode. Depending on the integrated light amount and wavelength suitable for the photoacid generator, a high-pressure mercury lamp or metal halide lamp categorized as a high-pressure discharge lamp, or a xenon lamp categorized as a short-arc discharge lamp, can be used. There is also no particular limitation on the integrated amount of light of wavelength less than 400 nm. The integrated light amount is generally 300 J/cm² or less, preferably 30 mJ/cm² or less. Herein, the integrated light amount can be measured with e.g. a commercially available light intensity meter (main body model: UIT-201, photodetector model: UVD-365PD etc., from Ushio Inc.).

[Step (e)]

In the temporary bonding method of the wafer and the support medium according to the present invention, there remains no or almost no residue of the cured water-processing temporary bonding material on the processed wafer; and almost all or all of the cured wafer-processing temporary bonding material remains adhered to the support medium. The residue of the cured wafer-processing temporary bonding material, if remains in a small amount on the processed wafer, is removed. It is feasible to remove the residue of the cured wafer-processing temporary bonding material by e.g. washing the processed wafer.

The processed wafer can be washed by the same component part washing method as explained above for the fifth step. The explanations of the washing method of the fifth embodiment are applicable to this wafer washing step assuming that the cured temporary bonding material, the processed component part and the substrate correspond to the cured wafer-processing temporary bonding material, the processed wafer and the support medium, respectively.

[Step (f)]

After the step (d), almost all or all of the residue of the cured wafer-processing temporary bonding material remains adhered to the support medium. In the step (f), the residue of the cured wafer-processing temporary bonding material is removed from the support medium. It is feasible to remove the residue of the cured wafer-processing temporary bonding material from the support medium by e.g. washing the support medium.

The support medium can be washed by the same substrate washing method as explained above for the sixth step. The explanations of the washing method of the six step are applicable to this support medium washing step assuming that the substrate and the cured temporary bonding material correspond to the support medium and the cured wafer-processing temporary bonding material, respectively.

[Step (g)]

The support medium obtained by the step (f) can be recycled in the step (a).

### EXAMPLES

The present invention will be described in more detail below by way of the following examples. It is noted that the following examples are illustrative and are not intended to limit the present invention thereto.

### Synthesis of Silicone Compounds (A)

### Preparation Example 1-1

A methacryloyl group-containing cage-like silsesquioxane compound was synthesized according to the following reaction scheme.

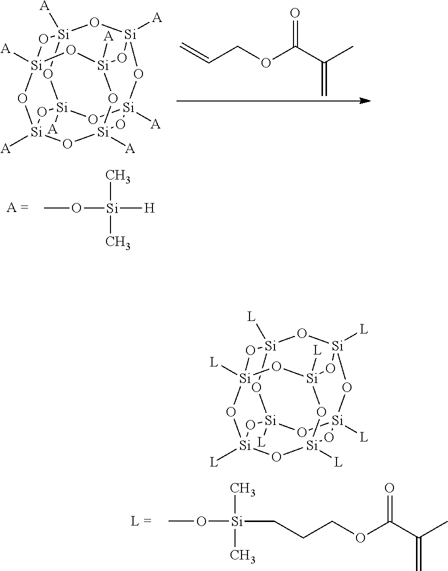

In a 200-mL eggplant-shaped flask, octa(dimethylsilyl)octasilsesquioxane (trade name: SH1310, available from U.S. Hybrid Plastics Inc.) (10.26 g), allyl methacrylate (10.81 g), toluene (100 mL) and a xylene solution (30 g) of platinum(0)-1,3-divinyl-1,1,3,3-tetramethyl complex as a platinum catalyst (platinum concentration: 2 mass %) were placed. The resulting mixture was reacted by stirring at room temperature (25° C.) over a night (24 hours), followed by removing toluene and unreacted allyl methacrylate from the reacted mixture through an evaporator. As a result, the methacryloyl group-containing cage-like silsesquioxane compound (resin (I-1)) (17.6 g) was obtained as a pale yellow liquid.

### Preparation Example 1-2

In a 500-mL flask, phenyltrimethoxysilane (trade name: KBM-103, available from Shin-Etsu Chemical Co., Ltd.) (30.01 g), dimethyldimethoxysilane (trade name: KBM-22, available from Shin-Etsu Chemical Co., Ltd.) (19.51 g), 3-(trimethoxysilyl)propylmethacrylate (19.43 g), isopropyl alcohol (80 g), water (65 g) and sodium hydroxide (0.20 g) were placed. The resulting mixture was reacted by stirring at a stirring rate of 200 rpm for 18 hours while heating the flask to 90° C. in an oil bath. The reacted mixture was left still and cooled to room temperature (25° C.). After that, isopropyl ether (100 mL) and water (100 mL) were added to the reacted mixture. The thus-formed organic layer was extracted by a separatory funnel. The organic layer was dehydrated with magnesium sulfate, followed by evaporating the organic solvent from the organic layer through an evaporator. As a result, a methacryloyl group-containing alkoxysilane hydrolysis condensate (resin (I-2)) (34.48 g) was obtained as a colorless transparent viscous liquid.

### Preparation of Compositions

### Preparation Example 2-1

A liquid composition 1 was prepared by adding, to the resin (I-1) (2.00 g) obtained in Preparation Example 1, bis(2,4,6-trimethylbenzoyl)phenylphosphine oxide (trade name: Irgacure 819, available from available from Chiba Specialty Chemicals Inc.) (0.03 g) as a photopolymerization initiator, CPI-110TF (trade name, available from San-Apro Ltd., the same applies to the following) (0.39 g) as a photoacid generator, lithium carbonate (0.88 g) of average particle size 2 μm as a metal compound, pentaerythritol triacrylate (trade name: Biscoat #300, available from Osaka Organic Chemical Industry Ltd., the same applies to the following) (0.48 g) as an additive, and then, kneading the resulting mixture with a three-roll mill. The photoacid generator CPI-110TF used was of the following structure.

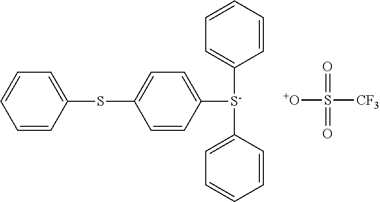 [SMILES: c1ccc(Sc2ccc([S-](c3ccccc3)c3ccccc3)cc2)cc1 ; O=S(=O)([OH2+])C(F)(F)F]

### Preparation Example 2-2

A liquid composition 2 was prepared in the same manner as in Preparation Example 2-1, except that potassium carbonate (1.40 g) of average particle size 10 μm was used as the metal compound in place of lithium carbonate (0.88 g).

### Preparation Example 2-3

A liquid composition 3 was prepared in the same manner as in Preparation Example 2-1, except that (2-hydroxyethyl)methacrylic acid (abbreviation: HEMA, available from Wako Pure Chemical Industries, Ltd.) (0.45 g) was used as the additive in place of pentaerythritol triacrylate (0.48 g).

### Preparation Example 2-4

A liquid composition 4 was prepared in the same manner as in Preparation Example 2-1, except that bis(η5-2,4-cyclopentadien-1-yl)-bis[2, 6-difluoro-3-(1H-pyrrol-1-yl)-phenyl]titanium (trade name: Irgacure 784, available from Chiba Specialty Chemicals Inc.) (0.03 g) was used as the photopolymerization initiator in place of bis(2,4,6-trimethylbenzoyl)phenylphosphine oxide (0.03 g).

### Preparation Example 2-5

A liquid composition 5 was prepared in the same manner as in Preparation Example 2-1, except that TPS-109 (0.41 g) was as the photoacid generator in place of CPI-110TF (0.39 g).

### Preparation Example 2-6

A liquid composition 6 was prepared in the same manner as in Preparation Example 2-1, except for using calcium hydroxide (2.11 g) as the metal compound in place of lithium carbonate.

### Preparation Example 2-7

A liquid composition 7 was prepared in the same manner as in Preparation Example 2-1, except that: calcium hydroxide (2.11 g) was as the metal compound in place of lithium carbonate; and HEMA (0.70 g) was used as the additive in place of Biscoat #300.

### Preparation Example 2-8

A liquid composition 8 was prepared in the same manner as in Preparation Example 2-1, except that: calcium hydroxide (2.11 g) was used as the metal compound in place of lithium carbonate; and TPS-109 (0.34 g) was used as the photoacid generator in place of CPI-110TF.

### Preparation Example 2-9

A liquid composition 9 was prepared in the same manner as in Preparation Example 2-1, except for using lithium hydroxide (1.28 g) as the metal compound in place of lithium carbonate.

### Preparation Example 2-10

A liquid composition 10 was prepared in the same manner as in Preparation Example 2-1, except that: the resin (I-2) was used as the compound (A) in place of the resin (I-1); and calcium hydroxide (2.11 g) was used as the metal compound in place of lithium carbonate.

### Preparation Example 2-11

A liquid composition 11 was prepared in the same manner as in Preparation Example 2-1, except that: the resin (I-2) was used as the compound (A) in place of the resin (I-1); and lithium hydroxide (1.28 g) was used as the metal compound in place of lithium carbonate.

### Preparation Example 2-12

A liquid composition 12 was prepared in the same manner as in Preparation Example 2-1, except that Biscoat #300 was not used as the additive.

### Preparation Example 2-13

A liquid composition 13 was prepared in the same manner as in Preparation Example 2-1, except that: TPS-109 (0.34 g) was used as the photoacid generator in place of CPI-110TF; and Biscoat #300 was not used as the additive.

### Synthesis of Hydrolysis Condensates (B)

### Preparation Example 3-1

In a 2-L flask equipped with a Dimroth condenser and a stirring blade, phenyltrimethoxysilane (trade name: KBM-103, available from Shin-Etsu Chemical Co., Ltd.) (140.40 g), dimethyldiethoxysilane (trade name: KBM-22, available from Shin-Etsu Chemical Co., Ltd.) (131.14 g), 3-(trimethoxysilyl)propylmethacrylate (available from Tokyo Chemical Industry Co., Ltd.) (48.56 g), isopropyl alcohol (213.32 g), water (160.96 g) and acetic acid (0.10 g) were placed. The resulting mixture was reacted by stirring at a stirring rate of 200 rpm for 6 hours while heating the flask to 90° C. in an oil bath. The reacted mixture was left still and cooled to room temperature (25° C.). After that, isopropyl ether (400 mL) and water (400 mL) were added to the reacted mixture. The thus-formed organic layer was extracted by a separatory funnel. The organic layer was dehydrated with magnesium sulfate, followed by evaporating the organic solvent from the organic layer through an evaporator. As a result, a methacryloyl group-containing alkoxysilane hydrolysis condensate (hereinafter also referred to as “hydrolysis condensate 1”) was obtained as a colorless transparent viscous liquid (170.68 g). The hydrolysis condensate 1 was dissolved in PGMEA to yield a PGME solution containing 33 mass % of the hydrolysis condensate 1 (hereinafter also referred to as “solution (B)-1”).

### Preparation Example 3-2

A methacryloyl group-containing alkoxysilane hydrolysis condensate (hereinafter also referred to as “hydrolysis condensate 2”) was obtained in the same manner as in Preparation Example 3-1, except for using methyltrimethoxysilane (88.91 g), dimethyldiethoxysilane (112.56 g), 3-(trimethoxysilyl)propylmethacrylate (70.11 g), isopropyl alcohol (203.79 g), water (144.45 g) and acetic acid (0.10 g). The hydrolysis condensate 2 was dissolved in PGMEA to yield a PGME solution containing 33 mass % of the hydrolysis condensate 2 (hereinafter also referred to as “solution (B)-2”).

### Example 1

A non-alkaline glass substrate (product number: 7059, available from Corning Inc., the same applies to the following) of diameter 100 mm and thickness 1.1 mm was subjected to surface polishing with cerium oxide fine particles (available from Aldrich Co., Ltd., the same applies to the following). Further, 0.6 g of the composition 1 prepared in Preparation Example 2-1 was coated on a silicon wafer of diameter 100 mm by a dispenser. A stacked unit 1 was formed by mating the composition coating on the silicon wafer with the non-alkaline glass. The thus-formed stacked unit 1 was tested by the following evaluation tests (1) to (6). The test results are shown in TABLE 3.

### Example 2

### Formation of Second Temporary Bonding Material Layer on Glass Substrate

A non-alkaline glass substrate of diameter 100 mm and thickness 1.1 mm was subjected to surface polishing with cerium oxide fine particles. Subsequently, the solution (B)-1 obtained in Preparation Example 3-1 was spin-coated on the surface of the non-alkaline glass substrate by a spin coater at 1000 rpm for 10 seconds. The coating was dried by heating on a hot plate of 200° C. for about 20 minutes, thereby forming a resin layer (II-1) of the hydrolysis condensate 1 as a secondary temporary bonding material layer on the surface of the non-alkaline glass substrate. The thickness of the resin layer (II-1) was measured by a stylus surface profiler (model: Dektak 8, available from U.S. Vecco Instruments Inc., the same applies to the following) and determined to be 0.7 μm.

(Application of Composition to Silicon Wafer)

0.6 g of the composition 1 prepared in Preparation Example 2-1 was coated on a silicon wafer of diameter 100 mm by a dispenser.

(Temporary Bonding of Silicon Wafer and Glass Substrate)

A stacked unit 2 was formed by mating the composition coating on the silicon wafer with the second temporary bonding material layer on the non-alkaline glass. The thus-formed stacked unit 2 was tested by the following evaluation tests (1) to (6). The test results are shown in TABLE 3.

### Example 3

A stacked unit 3 was formed in the same manner as in Example 2, except that the composition 2 was used in place of the composition 1. The thus-formed stacked unit 3 was tested by the following evaluation tests (1) to (6). The test results are shown in TABLE 3.

### Example 4

A stacked unit 4 was formed in the same manner as in Example 2, except that the composition 3 was used in place of the composition 1. The thus-formed stacked unit 4 was tested by the following evaluation tests (1) to (6). The test results are shown in TABLE 3.

### Example 5

A stacked unit 5 was formed in the same manner as in Example 2, except that the composition 4 was used in place of the composition 1. The thus-formed stacked unit 5 was tested by the following evaluation tests (1) to (6). The test results are shown in TABLE 3.

### Example 6

A stacked unit 6 was formed in the same manner as in Example 2, except that the composition 5 was used in place of the composition 1. The thus-formed stacked unit 6 was tested by the following evaluation tests (1) to (6). The test results are shown in TABLE 3.

### Example 7

### Formation of Second Temporary Bonding Material Layer on Glass Substrate

A non-alkaline glass substrate of diameter 100 mm and thickness 1.1 mm was subjected to surface polishing with cerium oxide fine particles. Subsequently, the solution (B)-2 obtained in Preparation Example 3-2 was spin-coated on the surface of the non-alkaline glass substrate by a spin coater at 1000 rpm for 10 seconds. The coating was dried by heating on a hot plate of 200° C. for about 20 minutes, thereby forming a resin layer (II-2) of the hydrolysis condensate 2 as a secondary temporary bonding material layer on the surface of the non-alkaline glass substrate. The thickness of the resin layer (II-2) was measured by a stylus surface profiler and determined to be 1.5 μm.

(Application of Composition to Silicon Wafer)

0.6 g of the composition 1 prepared in Preparation Example 2-1 was coated on a silicon wafer of diameter 100 mm by a dispenser.

(Temporary Bonding of Silicon Wafer and Glass Substrate)

A stacked unit 7 was formed by mating the composition coating on the silicon wafer with the second temporary bonding material layer on the non-alkaline glass. The thus-formed stacked unit 7 was tested by the following evaluation tests (1) to (6). The test results are shown in TABLE 3.

### Example 8

A stacked unit 8 was formed in the same manner as in Example 2, except that a borosilicate glass substrate was used in place of the non-alkaline glass substrate. The thus-formed stacked unit 8 was tested by the following evaluation tests (1) to (6). The test results are shown in TABLE 3.

### Example 9

A stacked unit 9 was formed in the same manner as in Example 2, except that a soda-lime glass substrate was used in place of the non-alkaline glass substrate. The thus-formed stacked unit 9 was tested by the following evaluation tests (1) to (6). The test results are shown in TABLE 3.

### Example 10

A stacked unit 10 was formed in the same manner as in Example 1, except that a non-alkaline glass substrate of diameter 100 mm and thickness 1.1 mm was used without being subjected to surface polishing with cerium oxide fine particles. The thus-formed stacked unit 10 was tested by the following evaluation tests (1) to (6). The test results are shown in TABLE 3.

### Example 11

A stacked unit 11 was formed in the same manner as in Example 1, except that the composition 6 was used in place of the composition 1. The thus-formed stacked unit 11 was tested by the following evaluation tests (1) to (6). The test results are shown in TABLE 3.

### Example 12

A stacked unit 12 was formed in the same manner as in Example 2, except that the composition 6 was used in place of the composition 1. The thus-formed stacked unit 12 was tested by the following evaluation tests (1) to (6). The test results are shown in TABLE 3.

### Example 13

A stacked unit 13 was formed in the same manner as in Example 2, except that the composition 7 was used in place of the composition 1. The thus-formed stacked unit 13 was tested by the following evaluation tests (1) to (6). The test results are shown in TABLE 3.

### Example 14

A stacked unit 14 was formed in the same manner as in Example 2, except that the composition 8 was used in place of the composition 1. The thus-formed stacked unit 14 was tested by the following evaluation tests (1) to (6). The test results are shown in TABLE 3.

### Example 15

A stacked unit 15 was formed in the same manner as in Example 2, except that: the composition 6 was used in place of the composition 1; and the resin layer (II-2) was formed from the solution (B)-2 as the second temporary bonding material layer in place of the formation of the resin layer (II-1) from the solution (B)-1. The thus-formed stacked unit 15 was tested by the following evaluation tests (1) to (6). The test results are shown in TABLE 3.

### Example 16

A stacked unit 16 was formed in the same manner as in Example 2, except that the composition 9 was used in place of the composition 1. The thus-formed stacked unit 16 was tested by the following evaluation tests (1) to (6). The test results are shown in TABLE 3.

### Example 17

A stacked unit 17 was formed in the same manner as in Example 2, except that the composition 10 was used in place of the composition 1. The thus-formed stacked unit 17 was tested by the following evaluation tests (1) to (6). The test results are shown in TABLE 3.

### Example 18

A stacked unit 18 was formed in the same manner as in Example 2, except that the composition 11 was used in place of the composition 1. The thus-formed stacked unit 18 was tested by the following evaluation tests (1) to (6). The test results are shown in TABLE 3.

### Example 19

A stacked unit 19 was formed in the same manner as in Example 2, except that the composition 12 was used in place of the composition 1. The thus-formed stacked unit 19 was tested by the following evaluation tests (1) to (6). The test results are shown in TABLE 3.

### Example 20

A stacked unit 20 was formed in the same manner as in Example 2, except that the composition 13 was used in place of the composition 1. The thus-formed stacked unit 6 was tested by the following evaluation tests (1) to (6). The test results are shown in TABLE 3.

### Comparative Example 1

A comparative liquid composition 1 was prepared in the same manner as in Preparation Example 2-1, except that lithium carbonate was not used as the metal compound. A comparative stacked unit 1 was then formed in the same manner as in Example 2, except that the comparative example 1 was used in place of the composition 1. The thus-formed comparative stacked unit 1 was tested by the following evaluation tests (1) to (6). The test results are shown in TABLE 3.

### Comparative Example 2

A comparative liquid composition 2 was prepared in the same manner as in Preparation Example 2-1, except that CPI-110TF was not used as the photoacid generator. A comparative stacked unit 2 was then formed in the same manner as in Example 2, except that the comparative example 2 was used in place of the composition 1. The thus-formed comparative stacked unit 2 was tested by the following evaluation tests (1) to (6). The test results are shown in TABLE 3.

### Comparative Example 3

A comparative liquid composition 3 was prepared in the same manner as in Preparation Example 2-1, except that Irgacure 819 was not used as the photopolymerization initiator. A comparative stacked unit 3 was then formed in the same manner as in Example 2, except that the comparative example 3 was used in place of the composition 1. The thus-formed comparative stacked unit 3 was tested by the following evaluation tests (1) to (6). The test results are shown in TABLE 3.

### Comparative Example 4

A comparative liquid composition 4 was prepared in the same manner as in Preparation Example 2-1, except that trimethylolpropane triacrylate (abbreviation: TMPTA) (1.92 g) was used as the additive in place of pentaerythritol triacrylate (0.48 g). A comparative stacked unit 4 was then formed in the same manner as in Example 2, except that the comparative example 4 was used in place of the composition 1. The thus-formed comparative stacked unit 4 was tested by the following evaluation tests (1) to (6). The test results are shown in TABLE 3.

### Comparative Example 5

A comparative stacked unit 5 was formed in the same manner as in Example 2 and was tested by the following evaluation tests (1) to (6). In this comparative example, however, the evaluation test (1) was conducted by irradiation with ultraviolet light from a high-pressure mercury lamp for 30 seconds, rather than by irradiation with LED light of wavelength 405 nm. The test results are shown in TABLE 3.

[Evaluation Tests]

(1) Bonding Property Test

Each of the stacked units 1 to 20 of Examples 1 to 20 and the comparative stacked units 1 to 4 of Comparative Examples 1 to 4 was irradiated with LED light of wavelength 405 nm for 30 seconds. The comparative stacked unit 5 of Comparative Example 5 was irradiated with ultraviolet light from a high-pressure mercury lamp for 30 seconds. Each stacked unit was then tested for the bonding property by lifting up the silicon wafer while fixing the substrate in a horizontal orientation. The test result was indicated by “◯” where there occurred no separation of the substrate and the silicon wafer. When there occurred separation of the substrate and the silicon wafer, the test result was indicated by “X”.

(2) Back Surface Grinding Resistance Test

The back surface of the silicon wafer of each of the stacked units 1 to 20 and the comparative stacked units 1, 2, 4 and 5 after the bonding was subjected to grinding by a grinder (DAG 810, available from Disco Corporation) with a diamond grindstone until the thickness of the silicon wafer became 50 μm. Then, the back surface of the silicon wafer of each stacked unit was tested for the occurrence or non-occurrence of any abnormality, such as cracking or separation, by an optical microscope (magnification: 100 times). The test result was evaluated as very good and indicated by “⊚” when there occurred no abnormality and there was no interference fringe visually found in the ground surface of the silicon wafer. When there occurred no abnormality, the test result was evaluated as good and indicated by “◯”. The test result was evaluated as poor and indicated by “X” when abnormality was found. When the back surface grinding resistance test was not performed, the test result was indicated by “-”. The back surface grinding resistance test was not performed on the stacked unit of Comparative Example 3 because separation occurred during the above bonding property test.

(3) Heat Resistance Test

Each of the stacked units 1 to 20 and the comparative stacked units 1, 2 and 4 was heated at 280° C. on a hot plate for 10 minutes in a nitrogen atmosphere after the back surface of the silicon wafer was grounded. Each stacked unit was then tested for the occurrence or non-occurrence of any appearance defect. The test result was evaluated as very good and indicated by “∘” when there was occurred no appearance defect. The test result was evaluated as good and indicated by “◯” when there occurred almost no appearance defect. When apparent appearance defect was found, the test result was evaluated as poor and indicated by “X”. When the heat resistance test was not performed, the test result was indicated by “-”. The heat resistance test was not performed on the stacked unit of Comparative Example 3 because of the same reason as for the above evaluation test (2). The heat resistance test was not also performed on the stacked unit of Comparative Example 5 because abnormality such as cracking occurred during the above back surface grinding resistance test.

(4) Separation Property Test

Each of the stacked units 1 to 20 and the comparative stacked units 1 and 2 was irradiated with ultraviolet light from a high-pressure mercury lamp for 300 seconds after the back surface of the silicon wafer was grounded. At this time, the ultraviolet light was emitted to the stacked unit (comparative stacked unit) from the back surface side opposite to the bonding surface side as viewed from the substrate. Each stacked unit was then tested for the separation property by, at room temperate, lifting up the substrate with tweezers and thereby separating the substrate from the silicon wafer. The test result was indicated by “◯” when the silicon wafer and the substrate were separated from each other without causing cracking in the silicon wafer and the substrate. When abnormality such as cracking was found, the test result was indicated by “X”. When the separation property test was not performed, the test result was indicated by “-”. The separation property test was not performed on the stacked units of Comparative Examples 3 and 5 because of the same reason as for the above evaluation tests (2) and (3). The separation resistance test was not also performed on the stacked unit of Comparative Example 4 because appearance defect occurred during the above heat resistance test.

(5) Evaluation of Residue on Silicon Wafer

After the above separation property test, the silicon wafer and the substrate were visually observed to test the amount of bonding material residue. The test result was indicated by “⊚” when the residue amount on the silicon wafer was less than 5% of the residue amount on the substrate. When the residue amount on the silicon wafer was less than 10% of the residue amount on the substrate, the test result was indicated by “◯”. When the residue amount on the silicon wafer was less than 50% of the residue amount on the substrate, the test result was indicated by “Δ”. The test result was indicated by “X” when the residue amount on the silicon wafer was 50% or more of the residue amount on the substrate. When the on-wafer residue evaluation test was not performed, the test was indicated by “-”. The on-wafer residue evaluation test was not performed on the stacked units of Comparative Examples 3 to 5 because of the same reason as for the above evaluation tests (2) to (4). The on-wafer residue evaluation test was not also performed on the stacked units of Comparative Examples 1 and 2 because abnormality such as cracking occurred in the wafer or substrate during the above separation property test.

(6) Washing Removability Test

After the above separation property test, the silicon wafer and the substrate to each of which the bonding material residue was adhered were washed with a mixed washing liquid of 25% aqueous tetramethylammonium hydroxide solution, isopropanol and N-methylpyrrolidone with a mass ratio of 50:25:25. The silicon wafer and the substrate were subsequently dried at 150° C. Then, the surfaces of the silicon wafer and the substrate were tested by an optical microscope (magnification: 100 times) for the presence or absence of bonding material residue and the occurrence or non-occurrence of abnormality such damage of the substrate. The test result was evaluated as very good and indicated by “⊚” when it was possible to remove the bonding material residue by washing within 3 minutes without causing abnormality such as damage of the substrate. When it was possible to remove the bonding material residue by washing within 15 minutes without causing abnormality such as damage of the substrate, the test result was evaluated as good and indicated by “◯”. The test result was evaluated as poor and indicated by “X” when bonding material residue and/or abnormality such as damage was found. When the washing removability test was not performed, the test result was indicated by “-”. The washing removability test was not performed on the stacked units of Examples 2 to 9 and 12 to 22 because these stacked units had good results in the above evaluation test (5). The washing removability test was not performed on the stacked units of Comparative Examples 1 to 5 because of the same reason as for the above evaluation tests (2) to (5).

The kinds of the resin layers (I), (II) and the substrates of Examples 1 to 20 and Comparative Examples 1 to 5 are summarized in TABLES 1 and 2. The evaluation test results are summarized in TABLE 3.

TABLE 1

| | | Ex. 1 | Ex. 2 | Ex. 3 | Ex. 4 | Ex. 5 | Ex. 6 | Ex. 7 |
|---|---|---|---|---|---|---|---|---|
| Resin | Silicone compound (A) | Resin (I-1) | Resin (I-1) | Resin (I-1) | Resin (I-1) | Resin (I-1) | Resin (I-1) | Resin (I-1) |
| layer | Photopolymerization | Irgacure 819 | Irgacure 819 | Irgacure 819 | Irgacure 819 | Irgacure 784 | Irgacure 819 | Irgacure 819 |
| (I) | initiator | | | | | | | |
| | Photoacid generator | CPI-110TF | CPI-110TF | CPI-110TF | CPI-110TF | CPI-110TF | TPS-109 | CPI-110TF |
| | Metal compound | Lithium | Lithium | Potassium | Lithium | Lithium | Lithium | Lithium |
| | | carbonate | carbonate | carbonate | carbonate | carbonate | carbonate | carbonate |
| | Additive | Biscoat #300 | Biscoat #300 | Biscoat #300 | HEMA | Biscoat #300 | Biscoat #300 | Biscoat #300 |
| Resin layer (II) | | — | Resin (II-1) | Resin (II-1) | Resin (II-1) | Resin (II-1) | Resin (II-1) | Resin (II-2) |
| Substrate | | #1 | #1 | #1 | #1 | #1 | #1 | #1 |
| | | Ex. 8 | Ex. 9 | Ex. 10 | Ex. 11 | Ex. 12 | Ex. 13 | Ex. 14 |
| Resin | Silicone compound (A) | Resin (I-1) | Resin (I-1) | Resin (I-1) | Resin (I-1) | Resin (I-1) | Resin (1-1) | Resin (I-1) |
| layer | Photopolymerization | Irgacure 819 | Irgacure 819 | Irgacure 819 | Irgacure 819 | Irgacure 819 | Irgacure 819 | Irgacure 819 |
| (I) | initiator | | | | | | | |
| | Photoacid generator | CPI-110TF | CPI-110TF | CPI-110TF | CPI-110TF | CPI-110TF | CPI-110TF | TPS-109 |
| | Metal compound | Lithium | Lithium | Lithium | Calcium | Calcium | Calcium | Calcium |
| | | carbonate | carbonate | carbonate | hydroxide | hydroxide | hydroxide | hydroxide |
| | Additive | Biscoat #300 | Biscoat #300 | Biscoat #300 | Biscoat #300 | Biscoat #300 | HEMA | Biscoat #300 |

| | | | | | | | |
|---|---|---|---|---|---|---|---|
| Resin layer (II) | Resin (II-1) | Resin (II-1) | — | — | Resin (II-1) | Resin (II-1) | Resin (II-1) |
| Substrate | #2 | #3 | #4 | #1 | #1 | #1 | #1 |

#1: Non-alkaline glass treated by ceria polishing
#2: Borosilicate glass treated by ceria polishing
#3: Soda-lime glass treated by ceria polishing
#4: Non-alkaline glass

TABLE 2

| | | Ex. 15 | Ex. 16 | Ex. 17 | Ex. 18 | Ex. 19 | Ex. 20 |
|---|---|---|---|---|---|---|---|
| Resin | Silicone compound (A) | Resin (I-1) | Resin (I-1) | Resin (I-2) | Resin (I-2) | Resin (I-1) | Resin (I-1) |
| layer | Photopolymerization | Irgacure 819 | Irgacure 819 | Irgacure 819 | Irgacure 819 | Irgacure 819 | Irgacure 819 |
| (I) | initiator | | | | | | |
| | Photoacid generator | CPI-110TF | CPI-110TF | CPI-110TF | CPI-110TF | CPI-110TF | TPS-109 |
| | Metal compound | Calcium | Lithium | Calcium | Lithium | Lithium | Calcium |
| | | hydroxide | hydroxide | hydroxide | hydroxide | carbonate | hydroxide |
| | Additive | Biscoat #300 | Biscoat #300 | Biscoat #300 | Biscoat #300 | —0 | — |

| | | | | | | |
|---|---|---|---|---|---|---|
| Resin layer (II) | Resin (II-2) | Resin (II-1) | Resin (II-1) | Resin (II-1) | Resin (II-1) | Resin (II-1) |
| Substrate | #1 | #1 | #1 | #1 | #1 | #1 |

| | | Comp. Ex. 1 | Comp. Ex. 2 | Comp. Ex. 3 | Comp. Ex. 4 | Comp. Ex. 5 |
|---|---|---|---|---|---|---|
| Resin | Silicone compound (A) | Resin (I-1) | Resin (I-1) | Resin (I-1) | — | Resin (I-1) |
| layer | Photopolymerization | Irgacure 819 | Irgacure 819 | — | Irgacure 819 | Irgacure 819 |
| (I) | initiator | | | | | |
| | Photoacid generator | CPI-110TF | — | CPI-110TF | CPI-110TF | CPI-110TF |
| | Metal compound | — | Lithium | Lithium | Calcium | Calcium |
| | | | carbonate | carbonate | hydroxide | hydroxide |
| | Additive | Biscoat #300 | Biscoat #300 | Biscoat #300 | TMPTA | Biscoat #300 |

| | | | | | |
|---|---|---|---|---|---|
| Resin layer (II) | Resin (II-1) | Resin (II-1) | Resin (II-1) | Resin (II-1) | Resin (II-1) |
| Substrate | #1 | #1 | #1 | #1 | #1 |

#1: Non-alkaline glass treated by ceria polishing

TABLE 3

| | Ex. 1 | Ex. 2 | Ex. 3 | Ex. 4 | Ex. 5 | Ex. 6 | Ex. 6 | Ex. 8 | Ex. 9 | Ex. 10 |
|---|---|---|---|---|---|---|---|---|---|---|
| Bonding property | ◯ | ◯ | ◯ | ◯ | ◯ | ◯ | ◯ | ◯ | ◯ | ◯ |
| Back surface grinding resistance | ◯ | ◯ | ◯ | ◯ | ◯ | ◯ | ◯ | ◯ | ◯ | ◯ |
| Heat resistance | ⊚ | ⊚ | ⊚ | ⊚ | ⊚ | ⊚ | ⊚ | ⊚ | ⊚ | ⊚ |
| Separation property | ◯ | ◯ | ◯ | ◯ | ◯ | ◯ | ◯ | ◯ | ◯ | ◯ |
| Residue on wafer | ◯ | ⊚ | ⊚ | ⊚ | ⊚ | ⊚ | ⊚ | ⊚ | ⊚ | Δ |
| Removability by washing | ◯ | — | — | — | — | — | — | — | — | ◯ |
| | Ex. 11 | Ex. 12 | Ex. 13 | Ex. 14 | Ex. 15 | Ex. 16 | Ex. 17 | Ex. 18 | Ex. 19 | Ex. 20 |
| Bonding property | ⊚ | ⊚ | ⊚ | ⊚ | ⊚ | ⊚ | ⊚ | ⊚ | ⊚ | ⊚ |
| Back surface grinding resistance | ⊚ | ⊚ | ⊚ | ⊚ | ⊚ | ⊚ | ⊚ | ⊚ | ⊚ | ⊚ |
| Heat resistance | ⊚ | ⊚ | ⊚ | ⊚ | ⊚ | ⊚ | ⊚ | ⊚ | ◯ | ◯ |
| Separation property | ⊚ | ⊚ | ⊚ | ⊚ | ⊚ | ⊚ | ⊚ | ⊚ | ⊚ | ⊚ |
| Residue on wafer | ◯ | ⊚ | ⊚ | ⊚ | ⊚ | ⊚ | ⊚ | ⊚ | ⊚ | ⊚ |
| Removability by washing | ⊚ | — | — | — | — | — | — | — | — | — |

| | Comp. | Comp. | Comp. | Comp. | Comp. |
|---|---|---|---|---|---|
| | Ex. 1 | Ex. 2 | Ex 3 | Ex 4 | Ex 5 |
| Bonding property | ◯ | ◯ | X | ◯ | ◯ |
| Back surface grinding resistance | ◯ | ◯ | — | ◯ | X |
| Heat resistance | ◯ | ◯ | — | X | — |
| Separation property | X | X | — | — | — |
| Residue on wafer | — | — | — | — | — |
| Removability by washing | — | — | — | — | — |

### DESCRIPTION OF REFERENCE NUMERALS

1: Component part
2: Substrate
3: Temporary bonding material
3a′: Layer of first curable composition
3a: First temporary bonding material layer
3b: Second temporary bonding material layer
10: Structural unit
20: Stacked unit

1. A first curable composition having flowability and comprising:
a photopolymerizable group-containing silicone compound (A);
a photopolymerization initiator that absorbs light of wavelength 400 nm or more;
a photoacid generator that absorbs light of wavelength less than 400 nm; and
at least one kind of metal compound selected from the group consisting of metal carbonates, metal hydroxides and metal oxides.

2. The first curable composition according to claim 1, wherein the photopolymerizable group-containing silicone compound (A) is either a cage-like silsesquioxane compound with an acryloyl group or a methacryloyl group, or a hydrolysis condensate of a composition containing at least an alkoxysilane compound of the general formula (3)
(R²)ᵥSi(OR³)₄₋ᵥ (3)
where R² is an organic moiety having at least one kind of group selected from the group consisting of acryloyl and methacryloyl groups; R³ is a methyl group or an ethyl group; v is an integer of 1 to 3; and, when there exist a plurality of R² and a plurality of R³, R² may be of the same kind or different kinds, and R³ may be of the same kind or different kinds.

3. A temporary bonding material comprising at least a first temporary bonding material layer in the form of a cured film of the first curable composition according to claim 1.

4. The temporary bonding material according to claim 3, further comprising a second temporary bonding material layer formed of a second curable composition containing at least a hydrolysis condensate of a photopolymerizable group-containing and hydrolyzable group-containing silicone compound (B).

5. The temporary bonding material according to claim 4, wherein the hydrolysis condensate of the photopolymerizable group-containing and hydrolyzable group-containing silicone compound (B) is a hydrolysis condensate obtained by hydrolysis and condensation of a composition containing at least an alkoxysilane compound of the general formula (5)
(R⁶)ₛSi(OR⁷)₄₋ₛ (5)
where R⁶ is an organic moiety having at least one kind of group selected from the group consisting of acryloyl and methacryloyl groups; R⁷ is a methyl group or an ethyl group; s is an integer of 1 to 3; and, when there exist a plurality of R⁶ and a plurality of R⁷, R⁶ may be of the same kind or different kinds, and R⁷ may be of the same kind or different kinds.

6. The temporary bonding material according to claim 4, wherein the second curable composition further contains a photopolymerization initiator.

7. A structural unit comprising a component part and a substrate temporarily bonded to each other via the temporary bonding material according to claim 3.

8. A method for temporarily bonding a component part to a substrate, the method comprising the following steps:
a first step of stacking the component part and the substrate together with an uncured temporary bonding material interposed therebetween, the uncured temporary bonding material having at least a layer of the first curable composition according to claim 1;
a second step of irradiating the uncured temporary bonding material with light of wavelength 400 nm or more, thereby curing the uncured temporary bonding material to form a structural unit in which the component part and the substrate are temporarily bonded to each other via the cured temporary bonding material;
a third step of processing the component part of the structural unit; and
a fourth step of, after the processing, separating the component part from the structural unit by irradiating the cured temporary bonding material of the structural unit with light of wavelength less than 400 nm.

9. The method according to claim 8, wherein the uncured temporary bonding material has a second temporary bonding material layer arranged in contact with the substrate and the layer of the first curable composition; and wherein the second temporary bonding material layer is a layer of a second curable composition containing at least a hydrolysis condensate of a photopolymerizable group-containing and hydrolyzable group-containing silicone compound (B).

10. The method according to claim 9, wherein the hydrolysis condensate of the photopolymerizable group-containing and hydrolyzable group-containing silicone compound (B) is a hydrolysis condensate obtained by hydrolysis and condensation of a composition containing at least an alkoxysilane compound of the general formula (5)
(R⁶)ₛSi(OR⁷)₄₋ₛ (5)
where R⁶ is an organic moiety having at least one kind of group selected from the group consisting of acryloyl and methacryloyl groups; R⁷ is a methyl group or an ethyl group; s is an integer of 1 to 3; and, when there exist a plurality of R⁶ and a plurality of R⁷, R⁶ may be of the same kind or different kinds, and R⁷ may be of the same kind or different kinds.

11. The method according to claim 8, further comprising removing a residue of the cured temporary bonding material from the substrate and then recycling the substrate.

12. A wafer-processing temporary bonding material for temporarily bonding a wafer, which has a front surface with a circuit forming area and a back surface to be processed, to a support medium by being interposed between the front surface of the wafer and the support medium, wherein the wafer-processing temporary bonding material is the temporary bonding material according to claim 3.

13. A method for temporarily bonding a wafer to a support medium, the wafer having a front surface with a circuit forming area and a back surface to be processed, the method comprising the following steps:
a step (a) of stacking the wafer and the support medium together with an uncured wafer-processing temporary bonding material interposed between the front surface of the wafer and the support medium, the uncured wafer-processing temporary bonding material having at least a layer of the first curable composition according to claim 1;
a step (b) of irradiating the uncured wafer-processing temporary bonding material with light of wavelength 400 nm or more, thereby curing the uncured wafer-processing temporary bonding material to form a wafer-processing structural unit in which the front surface of the wafer is temporarily bonded to the support medium via the cured wafer-processing temporary bonding material;
a step (c) of processing the back surface of the wafer of the wafer-processing structural unit; and
a step (d) of, after the processing, separating the wafer from the wafer-processing structural unit by irradiating the cured wafer-processing temporary bonding material of the wafer-processing structural unit with light of wavelength less than 400 nm.

14. The method according to claim 13, wherein the uncured wafer-processing temporary bonding material has a second temporary bonding material layer arranged in contact with the support medium and the layer of the first curable composition; and wherein the second temporary bonding material layer is a layer of a second curable composition containing at least a hydrolysis condensate of a photopolymerizable group-containing and hydrolyzable group-containing silicone compound (B).

15. The method according to claim 14, wherein the hydrolysis condensate of the photopolymerizable group-containing and hydrolyzable group-containing silicone compound (B) is a hydrolysis condensate obtained by hydrolysis and condensation of a composition containing at least an alkoxysilane compound of the general formula (5)
(R⁶)ₛSi(OR⁷)₄₋ₛ (5)
where R⁶ is an organic moiety having at least one kind of group selected from the group consisting of acryloyl and methacryloyl groups; R⁷ is a methyl group or an ethyl group; s is an integer of 1 to 3; and, when there exist a plurality of R⁶ and a plurality of R⁷, R⁶ may be of the same kind or different kinds, and R⁷ may be of the same kind or different kinds.

16. The method according to claim 13, further comprising removing a residue of the cured wafer-processing temporary bonding material from the support medium and then recycling the support medium.
